(19) United States
(12) Patent Application Publication
(10) Pub. No.: US 2023/0230937 A1
(43) Pub. Date: Jul. 20, 2023

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Hyunuk Jeon, Osan-si (KR); Yuseon Kang, Hwaseong-si (KR); Young-Min Ko, Hwaseong-si (KR); Dong Young Kim, Pohang-si (KR)

(21) Appl. No.: 17/930,820

(22) Filed: Sep. 9, 2022

(30) Foreign Application Priority Data
Jan. 17, 2022 (KR) 10-2022-0006435

(51) Int. Cl. H01L 23/00; H01L 23/535; H01L 23/532; H01L 27/11556; H01L 27/11529; H01L 27/11582; H01L 27/11573

(52) U.S. Cl. CPC H01L 23/562; H01L 23/535; H01L 23/5329; H01L 27/11556; H01L 27/11529; H01L 27/11582; H01L 27/11573

(57) ABSTRACT

Disclosed are a three-dimensional semiconductor memory device and an electronic system including the same. A semiconductor device includes a substrate, a cell array structure including a plurality of electrodes stacked on the substrate, a vertical channel structure that penetrates the cell array structure and is connected to the substrate, a conductive pad in an upper portion of the vertical channel structure, an interlayer insulating layer on the cell array structure, a bit line on the cell array structure, a bit line contact electrically connecting the bit line to the conductive pad, and a first stress release layer between the cell array structure and the bit line on a top surface of the interlayer insulating layer. The first stress release layer includes organosilicon polymer, and a carbon concentration of the first stress release layer is higher than that of the interlayer insulating layer.

### CROSS-REFERENCE TO RELATED APPLICATIONS

This U.S. non-provisional patent application claims priority under 35 U.S.C. § 119 to Korean Patent Application No. 10-2022-0006435, filed on Jan. 17, 2022, in the Korean Intellectual Property Office, the entire contents of which are hereby incorporated by reference.

### FIELD

The present disclosure relates to a three-dimensional semiconductor memory device and an electronic system including the same.

### BACKGROUND

A semiconductor device capable of storing a large amount of data may be desired as a part of an electronic system. Accordingly, studies are being conducted to increase data storage capacity of semiconductor devices. For example, semiconductor devices having three-dimensionally arranged memory cells, instead of two-dimensionally arranged memory cells, may be suggested.

### SUMMARY

An embodiment of the inventive concept provides a three-dimensional semiconductor memory device with improved reliability.

An embodiment of the inventive concept provides a method of fabricating a three-dimensional semiconductor memory device with improved reliability.

According to an embodiment of the inventive concept, a semiconductor device may include a substrate, a cell array structure on the substrate, the cell array structure including a plurality of electrodes which are stacked and spaced apart from each other, a vertical channel structure that penetrates the cell array structure and connected to the substrate, a conductive pad in an upper portion of the vertical channel structure, an interlayer insulating layer on the cell array structure, a bit line on the cell array structure and electrically connected to the conductive pad, and a first stress release layer between the cell array structure and the bit line on a top surface of the interlayer insulating layer. The first stress release layer may include organosilicon polymer, and a carbon concentration of the first stress release layer may be higher than a carbon concentration of the interlayer insulating layer.

According to an embodiment of the inventive concept, a semiconductor device may include a substrate, a first stack including a plurality of first electrodes stacked on the substrate and spaced apart from each other, a second stack including a plurality of second electrodes stacked on the first stack and spaced apart from each other, a first stress release layer between the first stack and the second stack, and a vertical channel structure that penetrates the first stack, the second stack, and the first stress release layer and connected to the substrate. The first stress release layer may include organosilicon polymer, and the first stress release layer may contain carbon (C), hydrogen (H), silicon (Si), and oxygen (O). The carbon concentration of the first stress release layer may be about or range from 20 at % to 40 at %, a silicon concentration of the first stress release layer may be about or range from 3 at % to 16 at %, and an oxygen concentration of the first stress release layer may be about or range from 3 at % to 16 at %.

According to an embodiment of the inventive concept, an electronic system may include a semiconductor device, which includes an input/output pad electrically connected to peripheral circuits, and a controller, which is electrically connected to the semiconductor device through the input/output pad and is configured to control the semiconductor device. The semiconductor device may include a lower level layer including a first substrate and the peripheral circuits on the first substrate, and an upper level layer on the lower level layer. The upper level layer may include a second substrate on the lower level layer, a cell array structure on the second substrate, the cell array structure including a plurality of electrodes stacked and spaced apart from each other, a vertical channel structure that penetrates the cell array structure and connected to the second substrate, an interlayer insulating layer on the cell array structure, and a stress release layer provided on the cell array structure on a top surface of the interlayer insulating layer. The stress release layer may include organosilicon polymer, and a density of the stress release layer may be lower than a density of the interlayer insulating layer.

According to an embodiment of the inventive concept, a method of fabricating a semiconductor device may include alternately stacking insulating layers and sacrificial layers on a substrate to form a mold layer, forming a stress release layer on the mold layer, the stress release layer including organosilicon polymer, forming a hard mask layer on the stress release layer, patterning the hard mask layer using a photolithography process, and anisotropically etching the mold layer using the hard mask layer as an etch mask. The stress release layer may be configured to release or reduce a stress exerted by the hard mask layer.

### BRIEF DESCRIPTION OF THE DRAWINGS

FIGS. 1A, 1B, 1C, and 1D are sectional views illustrating a method of etching a mold layer, according to a comparative example.

FIGS. 2A, 2B, 2C, and 2D are sectional views illustrating a method of etching a mold layer, according to an embodiment of the inventive concept.

FIG. 3 is a conceptual diagram illustrating an enlarged structure of a portion M of FIG. 2B.

FIG. 4 is a diagram schematically illustrating an electronic system including a semiconductor device according to an embodiment of the inventive concept.

FIG. 5 is a perspective view illustrating an electronic system including a semiconductor device according to an embodiment of the inventive concept.

FIGS. 6 and 7 are sectional views schematically illustrating semiconductor packages according to example embodiments of the inventive concept.

FIG. 8 is a plan view illustrating a semiconductor device according to an embodiment of the inventive concept.

FIG. 9A is a sectional view taken along a line I-I′ of FIG. 8.

FIG. 9B is a sectional view taken along a line II-II′ of FIG. 8.

FIGS. 10A, 11A, 12A, 13A, 14A, 15A, 16A, and 17A are sectional views taken along a line I-I′ of FIG. 8 to illustrate a method of fabricating a semiconductor device according to an embodiment of the inventive concept.

FIGS. 10B, 11B, 12B, 13B, 14B, 15B, 16B, and 17B are sectional views taken along a line II-II′ of FIG. 8 to illustrate a method of fabricating a semiconductor device according to an embodiment of the inventive concept.

FIG. 18 is a sectional view taken along the line I-I′ of FIG. 8 to illustrate a semiconductor device according to an embodiment of the inventive concept.

### DETAILED DESCRIPTION

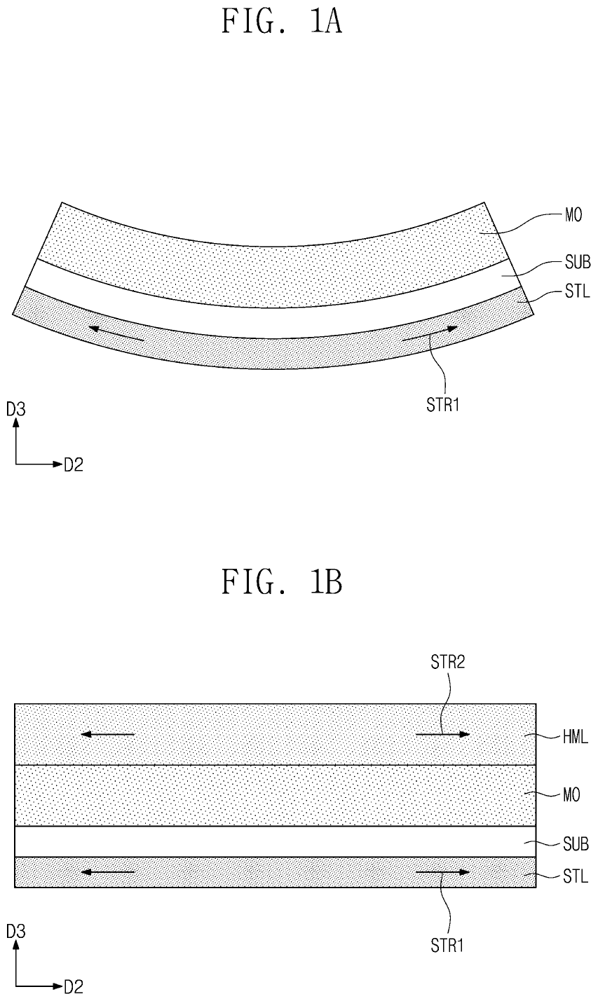

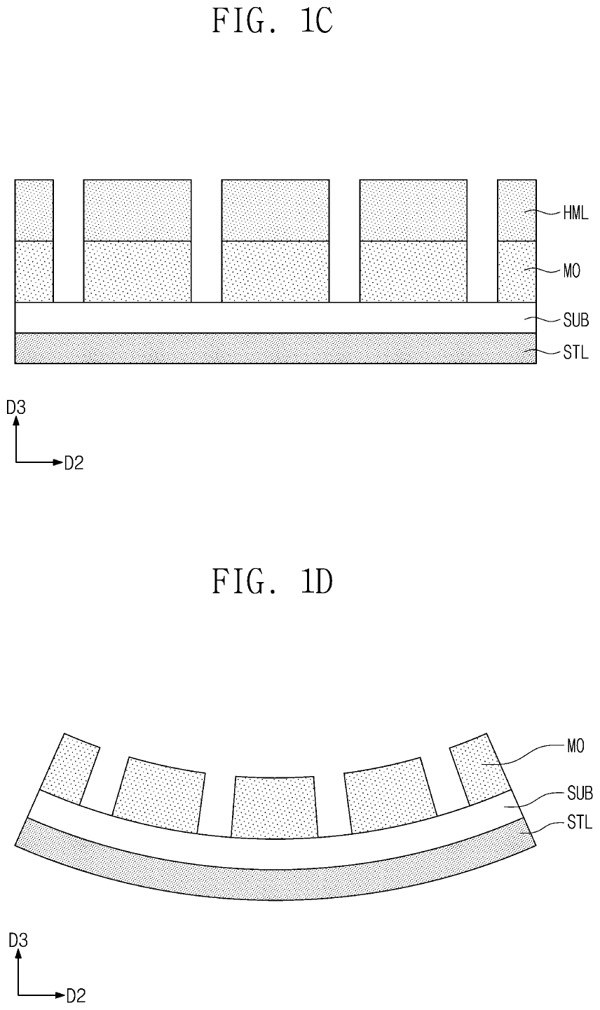

FIGS. 1A to 1D are sectional views illustrating a method of etching a mold layer, according to a comparative example. Elements described herein as “connected” may be electrically and/or physically connected. When elements are described as directly on or in direct contact with one another, no intervening elements are present.

Referring to FIG. 1A, a mold layer MO may be formed on a substrate SUB. The substrate SUB may be a semiconductor substrate (e.g., a silicon wafer). The mold layer MO may be a structure including at least two different layers which are alternately stacked. For example, the mold layer MO may be a stack, in which silicon oxide layers and silicon nitride layers are alternately stacked. The mold layer MO may be formed on a top surface of the substrate SUB.

A stress layer STL may be formed on a bottom surface of the substrate SUB. Due to the stress layer STL, a first stress STR1 may be exerted on the substrate SUB. The terms “first,” “second,” etc., may be used herein merely to distinguish one element or attribute from another. The first stress STR1 may be a tensile stress or a compressive stress. In an embodiment, the first stress STR1 may be a tensile stress. Owing to the first stress STR1 exerted on the substrate SUB, the substrate SUB and the mold layer MO may be bent.

In an embodiment, the stress layer STL may be formed of or include a silicon-based insulating layer. For example, the stress layer STL may include a silicon oxide layer, a silicon nitride layer, or a silicon oxynitride layer. By adjusting a process of depositing the stress layer STL, it may be possible to increase the first stress STR1 of the stress layer STL.

Referring to FIG. 1B, a hard mask layer HML may be formed on the mold layer MO. The hard mask layer HML may be an etch mask, which is used to etch the mold layer MO. The hard mask layer HML may have a relatively large thickness. In an embodiment, the hard mask layer HML may include an amorphous carbon layer.

The hard mask layer HML may exert a relatively large stress on a neighboring element. For example, the hard mask layer HML may exert a second stress STR2 on the substrate SUB. The second stress STR2 may be a tensile stress or a compressive stress. In an embodiment, the second stress STR2 may be a tensile stress.

Meanwhile, the first stress STR1 from the stress layer STL may be exerted on the bottom surface of the substrate SUB, and the second stress STR2 from the hard mask layer HML may be exerted on the top surface of the substrate SUB. Both of the first and second stresses STR1 and STR2 may be the tensile stress. In this case, the first stress STR1 exerted on the bottom surface of the substrate SUB may effectively cancel the second stress STR2 exerted on the top surface of the substrate SUB. As a result, the substrate SUB may be maintained to its original flat shape, without a deformation issue, such as warpage.

Referring to FIG. 1C, the hard mask layer HML may be patterned by a photolithography process. Thereafter, the mold layer MO may be patterned using the patterned hard mask layer HML as an etch mask.

In the case where the substrate SUB has a warpage issue, the accuracy in the photolithography process may be lowered. Furthermore, in order to etch the mold layer MO with a large thickness, it may be necessary to increase an etching depth in the process of patterning (i.e., etching) the mold layer MO. If the substrate SUB has the warpage issue, the process of deeply etching the mold layer MO may not be performed in a desired manner.

In the method of etching the mold layer MO according to the comparative example, to compensate the warpage issue of the substrate SUB caused by the hard mask layer HML with a high stress, the stress layer STL with a high stress may be formed on an opposite side of the hard mask layer HML. Thus, it may be possible to solve the accuracy problem in the photolithography process described above.

Referring to FIG. 1D, the hard mask layer HML may be selectively removed. As a result of the removal of the hard mask layer HML, the stress layer STL may remain or be left on the bottom surface of the substrate SUB. The substrate SUB may be bent again by (or due to stress exerted by) the stress layer STL.

In the comparative example, since the stress layer STL is left to cause the bending issue of the substrate SUB, an additional process failure may occur in a process performed after the etching of the mold layer MO. Furthermore, the etching process of the mold layer MO previously described with reference to FIG. 1C may include an anisotropic etching process using a high-power plasma. During the plasma etching process, it may be necessary to apply a ground voltage to the substrate SUB. However, due to the stress layer STL on the bottom surface of the substrate SUB, there may be a difficulty in uniformly applying the ground voltage to the substrate SUB. In this case, positive charges may be accumulated on the substrate SUB, and this may lead to a process failure, such as arcing.

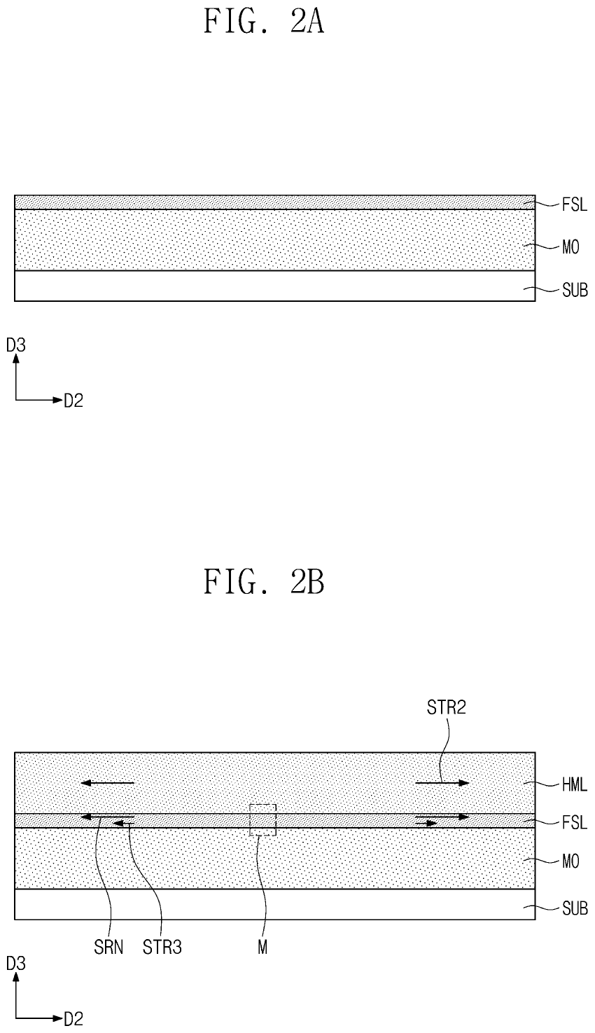

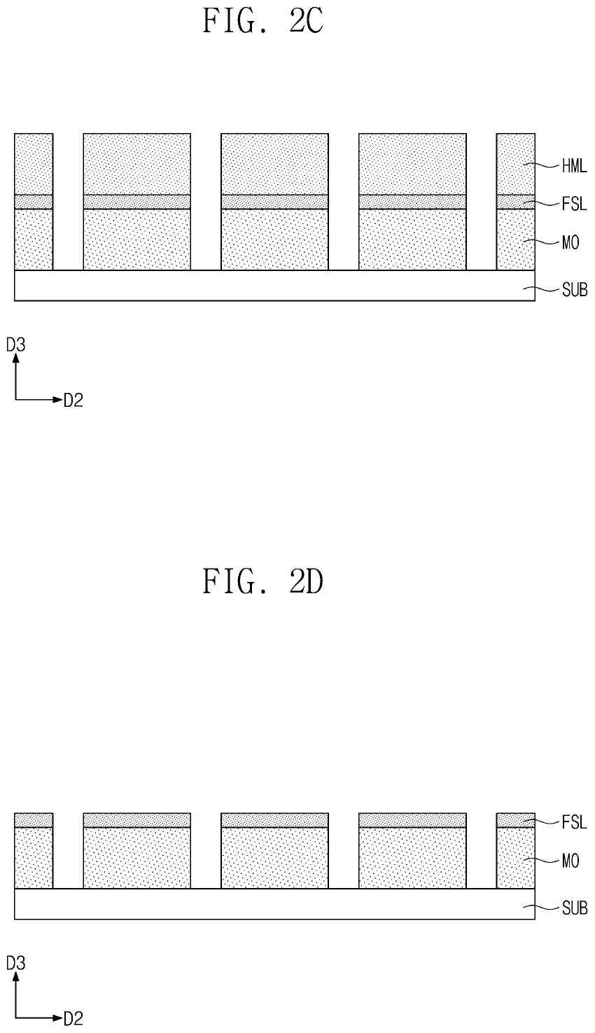

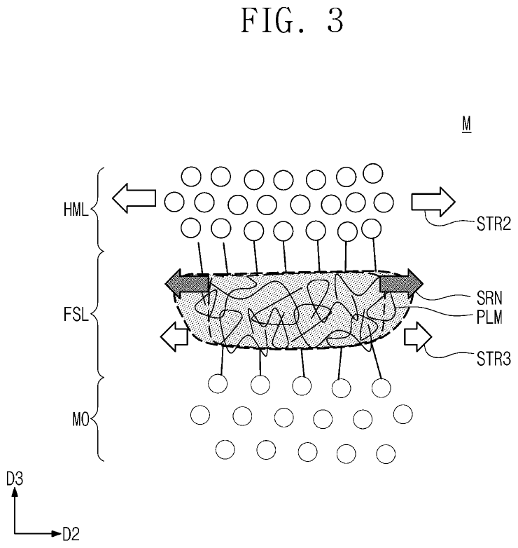

FIGS. 2A to 2D are sectional views illustrating a method of etching a mold layer, according to an embodiment of the inventive concept. FIG. 3 is a conceptual diagram illustrating an enlarged structure of a portion M of FIG. 2B.

Referring to FIG. 2A, the mold layer MO may be formed on the substrate SUB. The substrate SUB and the mold layer MO may be the same as or similar to those described with reference to FIG. 1A. A stress release layer FSL may be formed on the mold layer MO.

The stress release layer FSL may be formed of or include organosilicon polymer. The stress release layer FSL includes a polymer based on a siloxane unit of —Si—O—. The siloxane unit or a siloxane group may form a backbone of silicones of the organosilicon polymer. For example, the stress release layer FSL may be formed of or include at least one of polysiloxane-based polymers.

In an embodiment, the stress release layer FSL may include at least one polymer, each of which is represented by the following chemical formula 1.

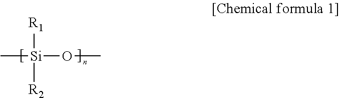

where R1 and R2 are each independently a hydrogen, an alkyl group having 1 to 5 carbon atoms, an alkenyl group having 2 to 6 carbon atoms, an alkynyl group having 2 to 6 carbon atoms, an alkoxy group having 1 to 5 carbon atoms, an aryl group having 6 to 10 carbon atoms, thiol group, a thiolalkyl group having 1 to 5 carbon atoms, a fluoroalkyl group having 1 to 5 carbon atoms, or an aminoalkyl group having 1 to 5 carbon atoms. Here, n is an integer between 100 and 10,000.

In another embodiment, the stress release layer FSL may include at least one polymer each of which is represented by the following chemical formula 2.

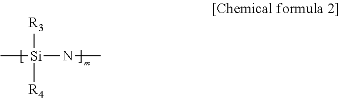

wherein R3 and R4 are each independently a hydrogen, an alkyl group having 1 to 5 carbon atoms, an alkenyl group having 2 to 6 carbon atoms, an alkynyl group having 2 to 6 carbon atoms, an alkoxy group having 1 to 5 carbon atoms, an aryl group having 6 to 10 carbon atoms, a thiol group, a thiolalkyl group having 1 to 5 carbon atoms, a fluoroalkyl group having 1 to 5 carbon atoms, or an aminoalkyl group having 1 to 5 carbon atoms. Here, m is an integer between 100 and 10,000.

In other embodiment, the polymer of the stress release layer FSL may be a copolymer containing not only the unit of the chemical formula 1 but also the unit of the chemical formula 2.

In still other embodiment, the stress release layer FSL may include a first polymer of the chemical formula 1 and a second polymer of the chemical formula 2. In other words, the stress release layer FSL may be a mixture of the first and second polymers.

In an embodiment, the organosilicon polymer of the stress release layer FSL may form a chain. In the case where the organosilicon polymer forms the chain, the stress release layer FSL may have an improved flowable property.

In an embodiment, the organosilicon polymer of the stress release layer FSL may include polydimethylsiloxane, polyvinylsiloxane, polysilazane, polysiloxane containing a thiol group (—SH), or polysiloxane containing a fluoro group (—F). Since the stress release layer FSL contains the organosilicon polymer, the stress release layer FSL may contain hydrogen (H), carbon (C), silicon (Si), and oxygen (O). The stress release layer FSL may further contain at least one of nitrogen (N), sulfur (S), or fluorine (F).

In an embodiment, the content or atomic fraction (i.e., atomic ratio) of the carbon (C) atoms may be highest in the stress release layer FSL. In the stress release layer FSL, an atomic fraction of the silicon (Si) atoms may be lower than an atomic fraction of the carbon (C) atoms. In the stress release layer FSL, an atomic fraction of the oxygen (O) atoms may be lower than that of the carbon (C) atoms. In the stress release layer FSL, the atomic fraction of the silicon (Si) atoms may be similar to the atomic fraction of the oxygen (O) atoms.

For example, in the stress release layer FSL, a concentration of carbon (C) may range from about 20 at % (atomic percent) to 40 at %, a concentration of silicon (Si) may range from about 3 at % to 16 at %, and a concentration of oxygen (O) may range from about 3 at % to 16 at %. The remaining elements of the stress release layer FSL other than the carbon (C), silicon (Si), and oxygen (O) atoms may be hydrogen (H) atoms. As described above, the stress release layer FSL may further contain at least one of nitrogen (N), sulfur (S), or fluorine (F). In the stress release layer FSL, the additional element (i.e., nitrogen (N), sulfur (S), or fluorine (F)) may have a concentration that is lower than a concentration of silicon (Si) or oxygen (O).

Due to the chain of the organosilicon polymers, the stress release layer FSL may be a flowable property. This is because, if the polymers form a chain, the polymers are not fixed and not bonded to each other, and the polymers can move freely. The stress release layer FSL may have a porous structure, which includes the chains of polymers and voids between the polymers. Thus, the stress release layer FSL may have a relatively low density. As an example, the density of the stress release layer FSL may be lower than the density of the mold layer MO.

Meanwhile, additional layers may not be formed on the bottom surface of the substrate SUB. In other words, the bottom surface of the substrate SUB may be exposed or free of additional layer(s) thereon.

Referring to FIG. 2B, the hard mask layer HML may be formed on the stress release layer FSL. The hard mask layer HML may be provided to have the same or similar features as that of FIG. 1B.

The hard mask layer HML may exert the second stress STR2 on the stress release layer FSL. Thus, an upper portion of the stress release layer FSL may have a first strain SRN by the second stress STR2.

Meanwhile, since the stress release layer FSL has a flowable property, the second stress STR2 may be effectively released, and a third stress STR3 may occur in a lower portion of the stress release layer FSL. The third stress STR3 may be considerably smaller than the second stress STR2.

The second stress STR2, which is produced by the hard mask layer HML, may be effectively released by the stress release layer FSL, and thus, the relatively small third stress STR3 may be exerted on the substrate SUB. Since a small stress is exerted on the substrate SUB, the substrate SUB may not be deformed and may be maintained to its original flat shape.

A stress-reducing mechanism of the stress release layer FSL will be described in more detail with reference to FIG. 3. The stress release layer FSL may include polymers PLM that are provided to form a chain. Due to the chain of the polymers PLM, the polymers PLM may be more easily moved in a direction parallel to a top surface of the mold layer MO. The stress release layer FSL may have a soft or flowable property, not a hard property. The stress release layer FSL may be adaptively or fluidically deformed against an external stress. In other words, the stress release layer FSL may have a high strain or strain resistance against the external stress.

In an embodiment, the upper portion of the stress release layer FSL in contact with the hard mask layer HML may be stretched in the direction parallel to the top surface of the mold layer MO by the second stress STR2. Accordingly, the upper portion of the stress release layer FSL may have the first strain SRN, as described.

The lower portion of the stress release layer FSL in contact with the mold layer MO may be hardly or slightly stretched by the relatively small third stress STR3. The lower portion of the stress release layer FSL may have a second strain smaller than the first strain SRN. Since any stress is not substantially exerted on the mold layer MO, the mold layer MO and the substrate SUB thereunder may not be bent and may be maintained to their original shapes.

Referring to FIG. 2C, the hard mask layer HML may be patterned by a photolithography process. The stress release layer FSL and the mold layer MO may be patterned using the patterned hard mask layer HML as an etch mask. In a method of etching the mold layer MO according to the present embodiment, the stress release layer FSL may be used to reduce or prevent a warpage issue from occurring in the substrate SUB. Thus, it may be possible to improve the accuracy of the photolithography process.

Referring to FIG. 2D, the hard mask layer HML may be selectively removed. In the present embodiment, since the stress layer STL of FIG. 1D is omitted, the substrate SUB may not be bent, even when the hard mask layer HML is removed. Thus, it may be possible to reduce or prevent a process failure in a subsequent process.

In the present embodiment, the bottom surface of the substrate SUB (which is opposite to the top surface having the mold layer MO and stress release layer FSL thereon) may not be covered with (e.g., may be free of) the stress layer STL and may be exposed to the outside. Accordingly, during the etching process of the mold layer MO, a ground voltage may be uniformly applied to the substrate SUB, and thus, a process failure, such as an arcing issue, may be reduced or prevented.

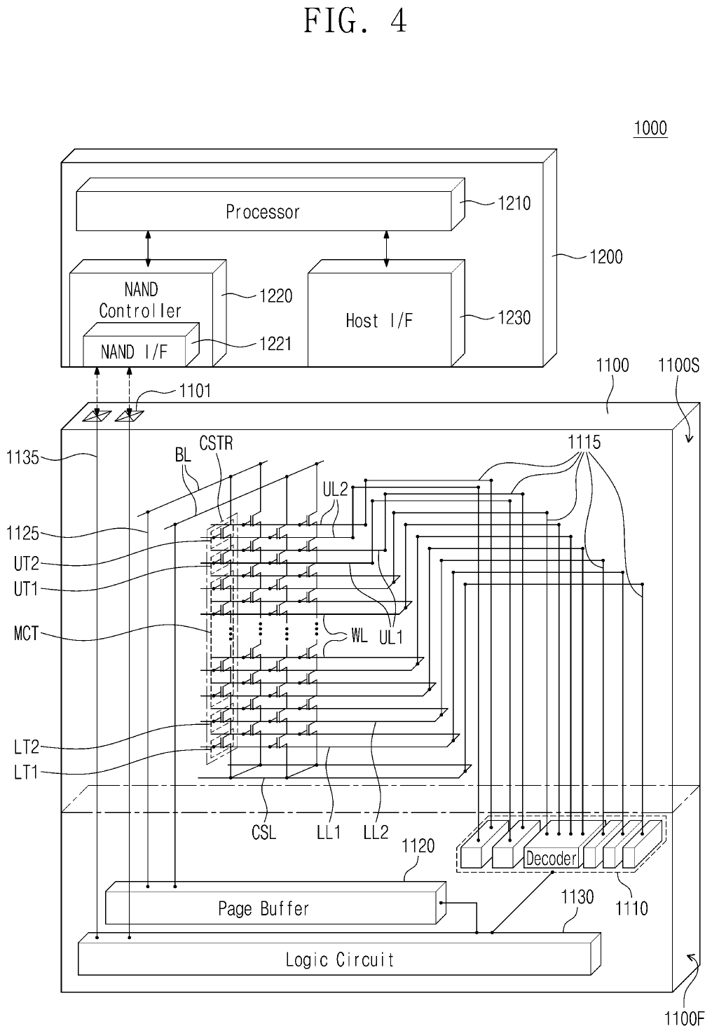

FIG. 4 is a diagram schematically illustrating an electronic system including a semiconductor device according to an embodiment of the inventive concept.

Referring to FIG. 4, an electronic system 1000 according to an embodiment of the inventive concept may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In an embodiment, the first structure 1100F may be disposed beside the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, the memory cell strings CSTR may constitute a three-dimensional memory cell structure. Each of the memory cell strings CSTR may be vertically extended. Each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary, according to embodiments.

In an embodiment, the upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be respectively used as gate electrodes of the memory cell transistors MCT, and the gate upper lines UL1 and UL2 may be respectively used as gate electrodes of the upper transistors UT1 and UT2.

In an embodiment, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT2 may be used for an erase operation of erasing data, which are stored in the memory cell transistors MCT, using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may be configured to perform a control operation on at least selected one of the memory cell transistors MCT. The decoder circuit 1110 and the page buffer 1120 may be controlled by the logic circuit 1130. The electronic system 1000 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The controller 1200 may include a processor 1210, a NAND controller 1220, and a host interface 1230. In an embodiment, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be configured to transmit and receive control commands, which are used to control the semiconductor device 1100, data, which are written in or read from the memory cell transistors MCT of the semiconductor device 1100, and so forth. The host interface 1230 may be configured to allow for communication between the electronic system 1000 and an external host. When the processor 1210 receives a control command transmitted from the external host through the host interface 1230, the processor 1210 may control the semiconductor device 1100 in response to the control command.

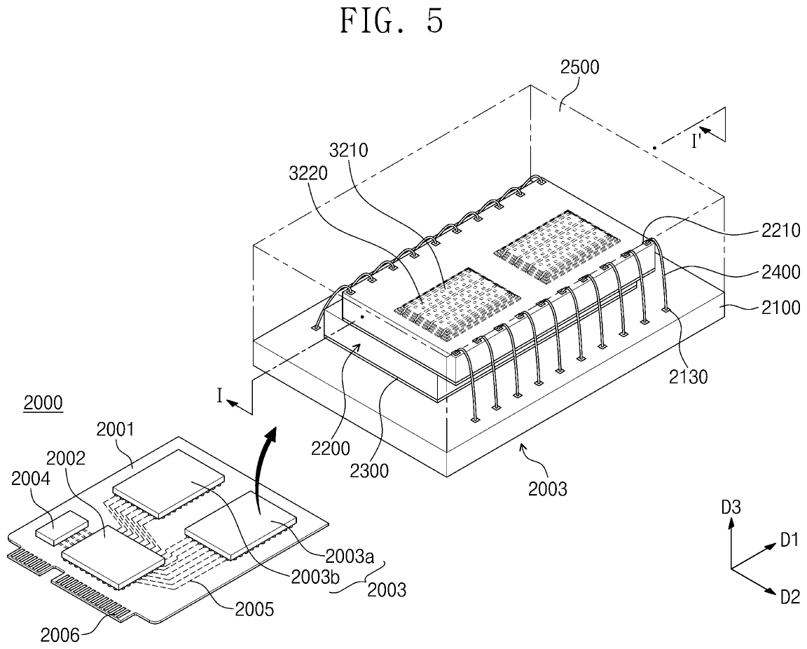

FIG. 5 is a perspective view schematically illustrating an electronic system including a semiconductor device according to an embodiment of the inventive concept.

Referring to FIG. 5, an electronic system 2000 according to an embodiment of the inventive concept may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 by interconnection patterns 2005, which are formed in the main substrate 2001.

The main substrate 2001 may include a connector 2006, which includes a plurality of pins coupled to an external host. In the connector 2006, the number and arrangement of the pins may be changed depending on a communication interface between the electronic system 2000 and the external host. In an embodiment, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In an embodiment, the electronic system 2000 may be driven by a power, which is supplied from the external host through the connector 2006. The electronic system 2000 may further include a Power Management Integrated Circuit (PMIC) that is configured to distribute a power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory, which relieves technical difficulties caused by a difference in speed between the semiconductor package 2003, which serves as a data storage device, and an external host. In an embodiment, the DRAM 2004 in the electronic system 2000 may serve as a cache memory and may be used as a storage space, which is configured to store data temporarily during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on respective bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400. An element that “covers” or is “covering” another element may extend on but may not require complete coverage of the other element.

The package substrate 2100 may be a printed circuit board including package upper pads 2130. Each of the semiconductor chips 2200 may include an input/output pad 2210. The input/output pad 2210 may correspond to the input/output pad 1101 of FIG. 4. Each of the semiconductor chips 2200 may include gate stacks 3210 and vertical channel structures 3220. Each of the semiconductor chips 2200 may include a semiconductor device, which will be described below, according to an embodiment of the inventive concept.

In an embodiment, the connection structure 2400 may be a bonding wire, which is provided to electrically connect the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively, in each of the first and second semiconductor packages 2003a and 2003b, the semiconductor chips 2200 may be electrically connected to each other by a connection structure including through-silicon vias (TSVs), rather than by the connection structure 2400 provided in the form of bonding wires.

In an embodiment, the controller 2002 and the semiconductor chips 2200 may be included in a single package. In an embodiment, the controller 2002 and the semiconductor chips 2200 may be mounted on an additional interposer substrate different from the main substrate 2001 and may be connected to each other through interconnection lines, which are provided in the interposer substrate.

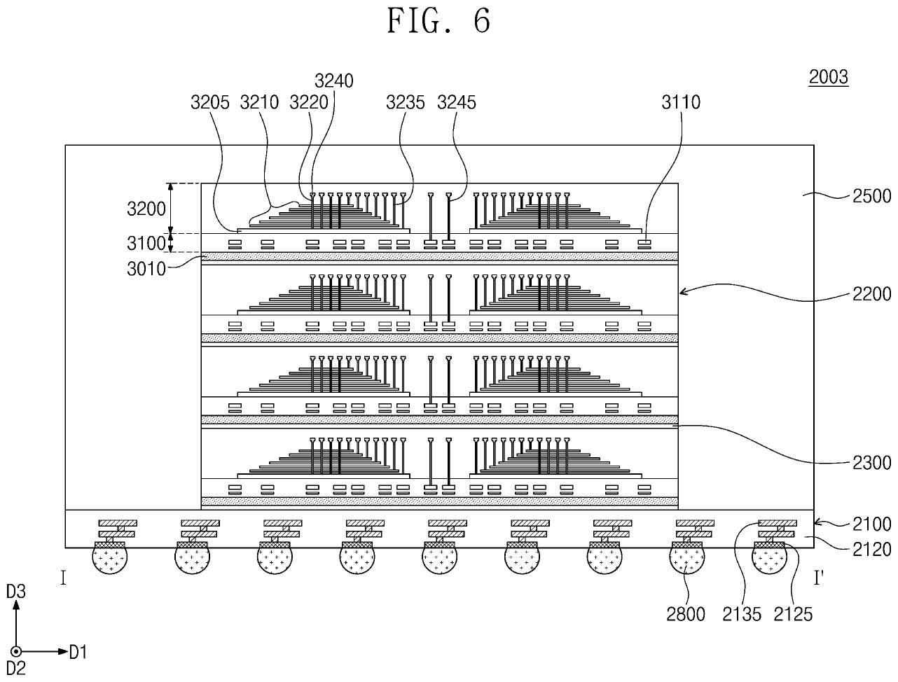

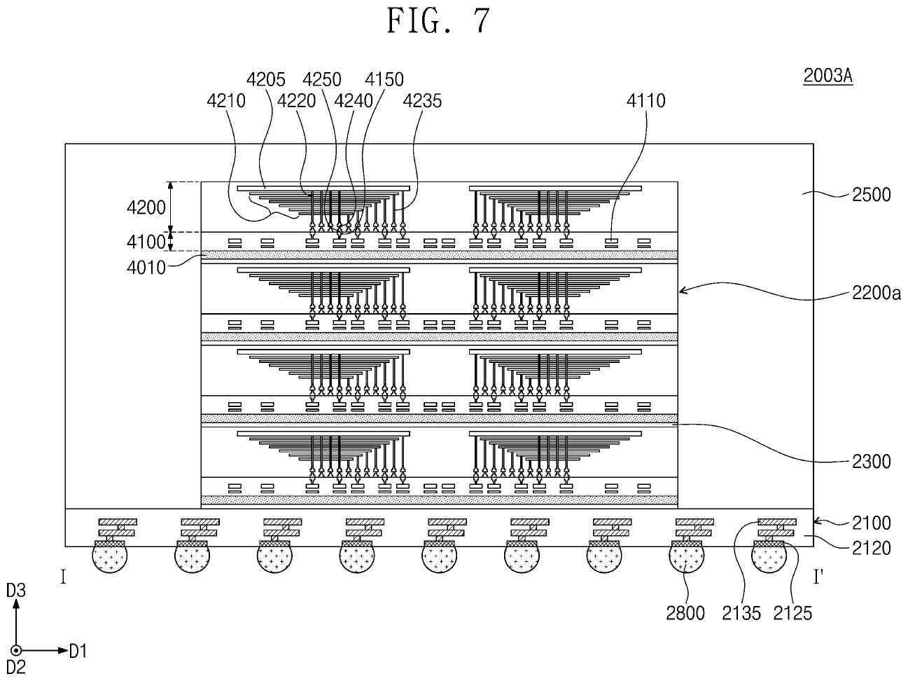

FIGS. 6 and 7 are sectional views, each of which schematically illustrates a semiconductor package according to an embodiment of the inventive concept. FIGS. 6 and 7 are sectional views, which are taken along a line I-I′ of FIG. 5, and illustrate two different examples of the semiconductor package of FIG. 5.

Referring to FIG. 6, the package substrate 2100 of the semiconductor package 2003 may be a printed circuit board. The package substrate 2100 may include a package substrate body portion 2120, the package upper pads 2130 (e.g., see FIG. 5), which are disposed on a top surface of the package substrate body portion 2120, lower pads 2125, which are disposed on or exposed through a bottom surface of the package substrate body portion 2120, and internal lines 2135, which are disposed in the package substrate body portion 2120 to electrically connect the package upper pads 2130 to the lower pads 2125. The package upper pads 2130 may be electrically connected to the connection structures 2400. The lower pads 2125 may be connected to the interconnection patterns 2005 of the main substrate 2001 of the electronic system 2000 shown in FIG. 5 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region including peripheral lines 3110. The second structure 3200 may include a source structure 3205, a stack 3210 on the source structure 3205, the vertical channel structures 3220 penetrating the stack 3210, bit lines 3240 electrically connected to the vertical channel structures 3220, and cell contact plugs 3235 electrically connected to the word lines WL (e.g., see FIG. 4) of the stack 3210.

Each of the semiconductor chips 2200 may include a penetration line 3245, which is electrically connected to the peripheral lines 3110 of the first structure 3100 and is extended into the second structure 3200. The penetration line 3245 may be disposed outside the stack 3210, and in an embodiment, the penetration line 3245 may be provided to further penetrate the stack 3210. Each of the semiconductor chips 2200 may further include the input/output pad 2210 (e.g., see FIG. 5), which is electrically connected to the peripheral lines 3110 of the first structure 3100.

Referring to FIG. 7, in the semiconductor package 2003A, each of the semiconductor chips 2200a may include a semiconductor substrate 4010, a first structure 4100 on the semiconductor substrate 4010, and a second structure 4200, which is provided on the first structure 4100 and is bonded to the first structure 4100 in a wafer bonding manner.

The first structure 4100 may include a peripheral circuit region including a peripheral line 4110 and first junction structures 4150. The second structure 4200 may include a source structure 4205, a stack 4210 between the source structure 4205 and the first structure 4100, vertical channel structures 4220 penetrating the stack 4210, bit lines 4240 electrically connected to the vertical channel structures 4220, and cell contact plugs 4235 electrically connected to the word lines WL (e.g., see FIG. 4) of the stack 4210.

The bit lines 4240 and the cell contact plugs 4235 may be electrically connected to the first junction structures 4150 of the first structure 4100 through second junction structures 4250. The second junction structures 4250 may be provided to be in contact with the first junction structures 4150, respectively, or may be bonded to the first junction structures 4150, respectively. The first junction structures 4150 and the second junction structures 4250 may be formed of or include copper (Cu).

Each of the semiconductor chips 2200a may further include the input/output pad 2210 (e.g., see FIG. 5), which is electrically connected to the peripheral line 4110 of the first structure 4100.

The semiconductor chips 2200 of FIG. 6 may be electrically connected to each other through the connection structures 2400, which are provided in the form of bonding wires. The semiconductor chips 2200a of FIG. 7 may be electrically connected to each other through the connection structures 2400, which are provided in the form of bonding wires. However, in an embodiment, semiconductor chips, which are stacked in in a single semiconductor package, such as the semiconductor chips 2200 of FIG. 6 or the semiconductor chips 2200a of FIG. 7, may be electrically connected to each other by through-silicon vias (TSVs).

The first structure 3100 of FIG. 6 and the first structure 4100 of FIG. 7 may correspond to a lower level layer in embodiments to be described below, and the second structure 3200 of FIG. 6 and the second structure 4200 of FIG. 7 may correspond to an upper level layer in the embodiments to be described below.

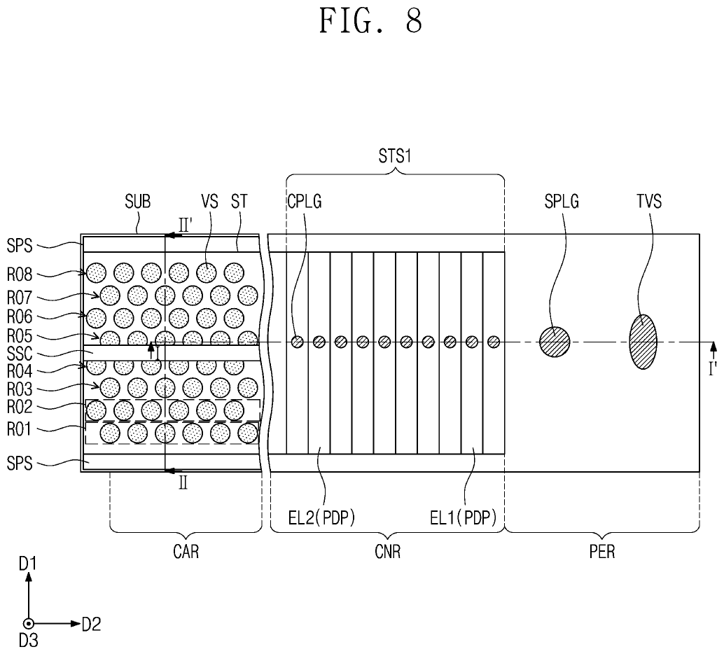

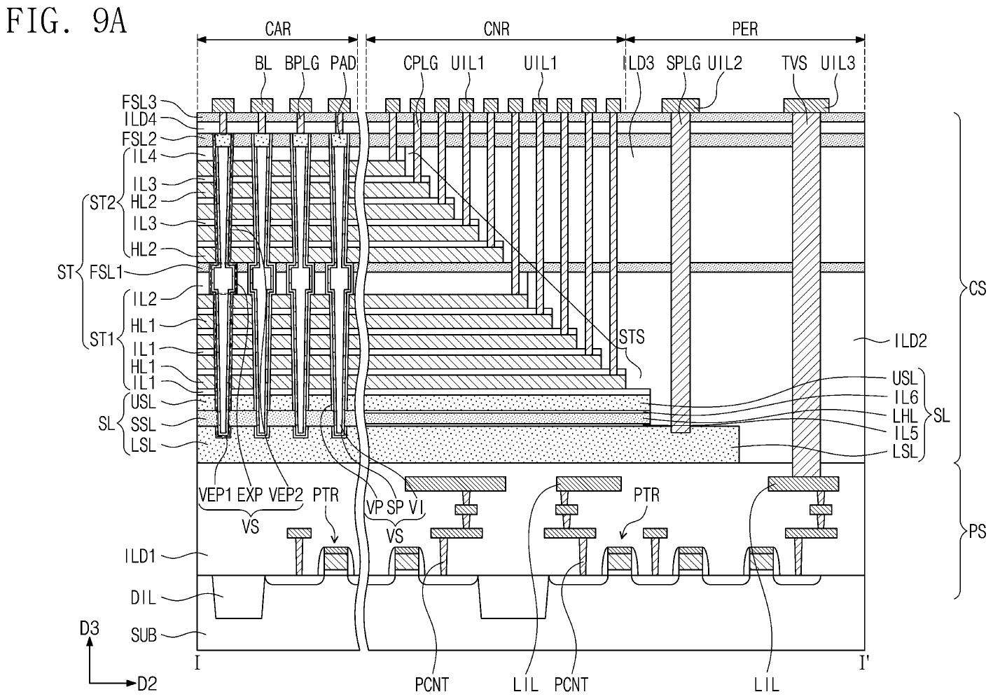

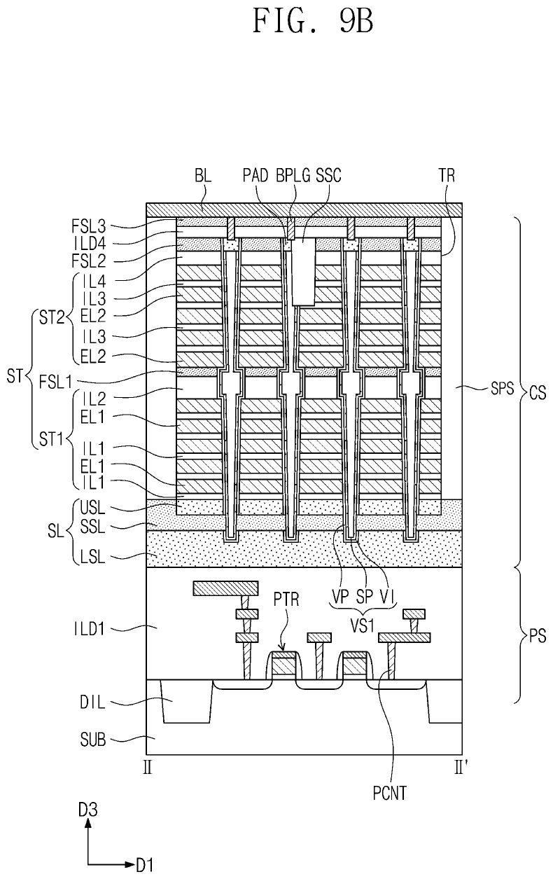

FIG. 8 is a plan view illustrating a semiconductor device according to an embodiment of the inventive concept. FIG. 9A is a sectional view taken along a line I-I′ of FIG. 8. FIG. 9B is a sectional view taken along a line II-II′ of FIG. 8.

Referring to FIGS. 8, 9A, and 9B, a lower level layer PS including peripheral transistors PTR may be disposed on a first substrate SUB. An upper level layer CS including a cell array structure ST may be disposed on the lower level layer PS. The first substrate SUB may be a silicon substrate, a silicon germanium substrate, a germanium substrate, or a single crystalline epitaxial layer grown on a single crystalline silicon substrate. The first substrate SUB may include active regions defined by a device isolation layer DIL.

The lower level layer PS may be a peripheral circuit region (or a peripheral circuit layer) including a decoder circuit, a page buffer, and a logic circuit. The lower level layer PS may include the peripheral transistors PTR, which are disposed on the active regions of the first substrate SUB. As described above, the peripheral transistors PTR may constitute the row and column decoders, the page buffer, the control circuit, the peripheral logic circuit, or the like.

More specifically, the first substrate SUB may include active regions that are defined by the device isolation layer DIL. At least one of the peripheral transistor PTR may be provided on each of the active regions.

The lower level layer PS may further include lower interconnection lines LIL, which are provided on the peripheral transistors PTR, and a first interlayer insulating layer ILD1, which is provided to cover the peripheral transistors and the lower interconnection lines LIL. A peripheral contact PCNT may be provided between the lower interconnection line LIL and the peripheral transistor PTR to electrically connect them to each other.

The first interlayer insulating layer ILD1 may have a multi-layered structure including a plurality of stacked insulating layers. For example, the first interlayer insulating layer ILD1 may include a silicon oxide layer, a silicon nitride layer, a silicon oxynitride layer, and/or a low-k dielectric layer. The upper level layer CS may be provided on the first interlayer insulating layer ILD1 of the lower level layer PS. The upper level layer CS will be described in more detail below.

The upper level layer CS may include a cell array region CAR, a cell contact region CNR, and a peripheral region PER. The cell contact region CNR may be located between the cell array region CAR and the peripheral region PER. The peripheral region PER may be an outer edge region of a semiconductor chip.

A second substrate SL may be provided on the first interlayer insulating layer ILD1. The second substrate SL may support the cell array structure ST provided on the cell array region CAR. The second substrate SL of the cell array region CAR may include a lower semiconductor layer LSL, a source semiconductor layer SSL, and an upper semiconductor layer USL, which are sequentially stacked. Each of the lower semiconductor layer LSL, the source semiconductor layer SSL, and the upper semiconductor layer USL may be formed of or include at least one of semiconductor materials (e.g., silicon (Si), germanium (Ge), silicon germanium (SiGe), gallium arsenic (GaAs), indium gallium arsenic (InGaAs), aluminum gallium arsenic (AlGaAs), or mixtures thereof).

Each of the lower semiconductor layer LSL, the source semiconductor layer SSL, and the upper semiconductor layer USL may have a single crystalline, amorphous, and/or polycrystalline structure. As an example, each of the lower semiconductor layer LSL, the source semiconductor layer SSL, and the upper semiconductor layer USL may include an n-type polysilicon layer doped with impurities. The lower semiconductor layer LSL, the source semiconductor layer SSL, and the upper semiconductor layer USL may have doping concentrations that are different from each other.

The source semiconductor layer SSL may be interposed between the lower semiconductor layer LSL and the upper semiconductor layer USL. The lower semiconductor layer LSL and the upper semiconductor layer USL may be electrically connected to each other by the source semiconductor layer SSL.

The second substrate SL of the cell contact region CNR may include the lower semiconductor layer LSL, a fifth insulating layer IL5, a lower sacrificial layer LHL, a sixth insulating layer IL6, and the upper semiconductor layer USL, which are sequentially stacked. The fifth and sixth insulating layers IL5 and IL6 may include a silicon oxide layer, and the lower sacrificial layer LHL may include a silicon nitride layer or a silicon oxynitride layer.

The lower semiconductor layer LSL of the second substrate SL may be extended from the cell array region CAR to the peripheral region PER. The lower semiconductor layer LSL may be extended to a portion of the peripheral region PER but may not be extended to another portion of the peripheral region PER. In other words, the peripheral region PER may include a portion, in which the lower semiconductor layer LSL is not provided.

The cell array structure ST may be provided on the cell array region CAR and the cell contact region CNR of the second substrate SL. The cell array structure ST may include a first stack ST1 and a second stack ST2 on the first stack ST1. A second interlayer insulating layer ILD2 and a third interlayer insulating layer ILD3 may be provided on the second substrate SL. A top surface of the second interlayer insulating layer ILD2 may be coplanar with a top surface of the first stack ST1. A top surface of the third interlayer insulating layer ILD3 may be coplanar with a top surface of the second stack ST2. The second and third interlayer insulating layers ILD2 and ILD3 may cover a staircase structure STS of the cell array structure ST.

The first stack ST1 may include first electrodes EL1, which are stacked in a direction (i.e., a third direction D3) perpendicular to the second substrate SL. The first stack ST1 may further include first insulating layers IL1 separating the stacked first electrodes EL1 from each other. The first insulating layers IL1 and the first electrodes EL1 may be alternately stacked in the first stack ST1. A second insulating layer IL2 may be provided as the uppermost layer of the first stack ST1. The second insulating layer IL2 may be thicker than each of the first insulating layers IL1.

The second stack ST2 may include second electrodes EL2, which are stacked on the first stack ST1 in the third direction D3. The second stack ST2 may further include third insulating layers IL3, which separate the stacked second electrodes EL2 from each other. The third insulating layers IL3 and the second electrodes EL2 of the second stack ST2 may be alternately stacked. A fourth insulating layer IL4 may be provided as the uppermost layer of the second stack ST2. The fourth insulating layer IL4 may be thicker than each of the third insulating layers IL3.

The cell array structure ST may include the staircase structure STS on the cell contact region CNR. The staircase structure STS may be a portion of the cell array structure ST, which is extended from the cell array region CAR to the cell contact region CNR in a second direction D2. In other words, the first and second electrodes EL1 and EL2 of the cell array structure ST may constitute the staircase structure STS that is extended from the cell array region CAR to the cell contact region CNR. The staircase structure STS on the cell contact region CNR may be connected to the cell array structure ST on the cell array region CAR. A height of the staircase structure STS may decrease with decreasing distance to the peripheral region PER. In other words, the height of the staircase structure STS may decrease with decreasing distance to or in the second direction D2.

The lowermost one of the first electrodes EL1 of the cell array structure ST may serve as the first lower selection line LL1 (e.g., see FIG. 4), and the next lowermost one of the first electrodes EL1 on the lowermost first electrode EL1 may serve as the second lower selection line LL2 (e.g., see FIG. 4).

The uppermost one of the second electrodes EL2 of the cell array structure ST may serve as the first string selection line UL1 (e.g., see FIG. 4), and the next uppermost one of the second electrodes EL2 below the uppermost second electrode EL2 may serve as the second string selection line UL2 (e.g., see FIG. 4). The terms upper, lower, above, below, etc. (and variations thereof) may be used herein depending on the orientations shown in the figures. The remaining ones of the first and second electrodes EL1 and EL2, except for the first and second lower selection lines and the first and second string selection lines, may serve as the word lines WL (e.g., see FIG. 4).

The first and second electrodes EL1 and EL2 may include end portions that are provided to constitute the staircase structure STS. For example, the end portions of the first and second electrodes EL1 and EL2 may be sequentially stacked to have horizontal lengths different from each other in the second direction D2 and may be exposed to the outside of the cell array structure ST.

The first and second electrodes EL1 and EL2 may be formed of or include at least one conductive material selected from the group consisting of doped semiconductor materials (e.g., doped silicon), metallic materials (e.g., tungsten, copper, or aluminum), conductive metal nitrides (e.g., titanium nitride or tantalum nitride), and transition metals (e.g., titanium or tantalum). At least one of first to fourth insulating layers IL1 to IL4 may include a silicon oxide layer.

A plurality of vertical channel structures VS may be provided on the cell array region CAR to penetrate the cell array structure ST. Each of the vertical channel structures VS may include a vertical insulating pattern VP, a vertical semiconductor pattern SP, and an insulating gapfill pattern VI. The vertical semiconductor pattern SP may be interposed between the vertical insulating pattern VP and the insulating gapfill pattern VI. A conductive pad PAD may be provided in an upper portion of each of the vertical channel structures VS.

The insulating gapfill pattern VI may have a circular pillar shape. The vertical semiconductor pattern SP may be extended from the lower semiconductor layer LSL to the conductive pad PAD in the third direction D3 to cover or otherwise extend along a surface of the insulating gapfill pattern VI. The vertical semiconductor pattern SP may be shaped like a pipe with an open top end. The vertical insulating pattern VP may cover or otherwise extend along an outer surface of the vertical semiconductor pattern SP and may be extended from the lower semiconductor layer LSL to a top surface of a fourth interlayer insulating layer ILD4 in the third direction D3. The vertical insulating pattern VP may be shaped like a pipe with an open top end. The vertical insulating pattern VP may be interposed between the cell array structure ST and the vertical semiconductor pattern SP.

The vertical insulating pattern VP may include one or more layers. In an embodiment, the vertical insulating pattern VP may include a data storing layer. In an embodiment, the vertical insulating pattern VP may include a tunnel insulating layer, a charge storing layer, and a blocking insulating layer constituting a data storing layer of a NAND FLASH memory device.

For example, the charge storing layer may be a trap insulating layer, a floating gate electrode, or an insulating layer including conductive nanodots. The charge storing layer may include at least one of a silicon nitride layer, a silicon oxynitride layer, a silicon-rich nitride layer, a nanocrystalline silicon layer, or a laminated trap layer. The tunnel insulating layer may be formed of or include a material whose band gap larger is larger than the charge storing layer. The tunnel insulating layer may include a high-k dielectric layer (e.g., an aluminum oxide layer and a hafnium oxide layer) or a silicon oxide layer. The blocking insulating layer may include a silicon oxide layer.

The vertical semiconductor pattern SP may be formed of or include at least one of semiconductor materials (e.g., silicon (Si), germanium (Ge), or mixtures thereof). In addition, the vertical semiconductor pattern SP may be formed of or include at least one of doped semiconductor materials or undoped (i.e., intrinsic) semiconductor materials. The vertical semiconductor pattern SP including the semiconductor material may be used as channel regions of transistors constituting a memory cell string.

The conductive pad PAD may cover a top surface of the vertical semiconductor pattern SP and a top surface of the insulating gapfill pattern VI. The conductive pad PAD may be formed of or include at least one of doped semiconductor materials or conductive materials. A bit line contact BPLG may be electrically connected to the vertical semiconductor pattern SP through the conductive pad PAD.

The source semiconductor layer SSL may be in direct contact with a lower sidewall of each of the vertical semiconductor patterns SP. The source semiconductor layer SSL may electrically connect the vertical semiconductor patterns SP to each other. For example, all of the vertical semiconductor patterns SP may be electrically connected to the second substrate SL. The second substrate SL may serve as source regions of memory cells. A common source voltage may be applied to the second substrate SL through a source contact plug SPLG, which will be described below.

Each of the vertical channel structures VS may include a first vertical extended portion VEP1 penetrating the first stack ST1, a second vertical extended portion VEP2 penetrating the second stack ST2, and an expanded portion EXP between the first and second vertical extended portions VEP1 and VEP2. The expanded portion EXP may be provided in the second insulating layer IL2.

The first vertical extended portion VEP1 may have a diameter increasing in an upward direction. The second vertical extended portion VEP2 may also have a diameter increasing in the upward direction. A diameter of the expanded portion EXP may be larger than the largest diameter of the first vertical extended portion VEP1 and may be larger than the largest diameter of the second vertical extended portion VEP2.

A plurality of separation structures SPS may be provided to penetrate the cell array structure ST (e.g., see FIG. 9B). The cell array structure ST may be horizontally divided into a plurality of structures by the separation structures SPS. For example, each electrode EL1 or EL2 in the cell array structure ST may be horizontally divided into a plurality of electrodes by the separation structures SPS. The separation structures SPS may be formed of or include at least one of insulating materials (e.g., silicon oxide).

The fourth interlayer insulating layer ILD4 may be provided on the cell array structure ST and the third interlayer insulating layer ILD3.

Bit line contacts BPLG may be provided to penetrate the fifth interlayer insulating layer and may be coupled to the conductive pads PAD, respectively. The bit lines BL may be disposed on the fifth interlayer insulating layer. The bit lines BL may be extended in a first direction D1 to be parallel to each other. The bit lines BL may be electrically connected to the vertical channel structures VS, respectively, through the bit line contacts BPLG.

A plurality of first upper interconnection lines UIL1 may be provided on the fifth interlayer insulating layer of the cell contact region CNR. Cell contact plugs CPLG may be provided to vertically extend from the first upper interconnection lines UIL1 to the staircase structure STS.

The cell contact plugs CPLG may be respectively coupled to exposed portions of the first and second electrodes EL1 and EL2 of the staircase structure STS. The cell contact plugs CPLG may be sequentially coupled to end portions of the first and second electrodes EL1 and EL2, respectively. The first and second electrodes EL1 and EL2 may be electrically connected to the first upper interconnection lines UIL1, respectively, through the cell contact plugs CPLG.

A second upper interconnection line UIL2 may be provided on the fifth interlayer insulating layer of the peripheral region PER. The source contact plug SPLG may be provided to vertically extend from the second upper interconnection line UIL2 to the lower semiconductor layer LSL. The second upper interconnection line UIL2 may be electrically connected to the second substrate SL through the source contact plug SPLG. A common source voltage may be applied to the second substrate SL through the second upper interconnection line UIL2 and the source contact plug SPLG.

A third upper interconnection line UIL3 may be provided on the fifth interlayer insulating layer of the peripheral region PER. A through via TVS may be provided to vertically extend from the third upper interconnection line UIL3 to the lower interconnection line LIL of the lower level layer PS. The upper level layer CS may be electrically connected to the lower level layer PS through the through via TVS.

Referring back to FIGS. 8 and 9B, a cutting structure SSC may be provided on the cell array region CAR. The cutting structure SSC may be extended in the second direction D2 to cross an upper portion of the cell array structure ST. The cutting structure SSC may have a line shape, when viewed in a plan view.

The vertical channel structures VS may be two-dimensionally arranged to form first to eighth rows RO1-RO8. The first to eighth rows RO1-RO8 may be arranged in the first direction D1 to be spaced apart from each other by a constant distance. The vertical channel structures VS in each of the first to eighth rows RO1-RO8 may be arranged in the second direction D2 to be spaced apart from each other with the same pitch.

The vertical channel structures VS in adjacent rows may be offset from each other in the second direction D2. For example, the vertical channel structures VS of the first row RO1 may be offset from the vertical channel structures VS of the second row RO2 in the second direction D2.

The cutting structure SSC may be provided between the fourth row RO4 and the fifth row RO5 and may be extended in the second direction D2. The cutting structure SSC may be vertically overlapped with at least a portion of each of the vertical channel structures VS of the fourth and fifth rows RO4 and RO5. In other words, the cutting structure SSC may be extended to cross the vertical channel structures VS of the fourth and fifth rows RO4 and RO5.

The cutting structure SSC may be provided to penetrate the uppermost one of the second electrodes EL2 (i.e., the first string selection line UL1 of FIG. 4) and the next uppermost one of the second electrodes EL2 (i.e., the second string selection line UL2 of FIG. 4). The first string selection line UL1 of FIG. 4 may be divided into two lines by the cutting structure SSC. The second string selection line UL2 of FIG. 4 may be divided into two lines by the cutting structure SSC. The cutting structure SSC may be provided to penetrate a portion of the conductive pad PAD. The cutting structure SSC may also be provided to partially penetrate an upper portion of the vertical channel structure VS.

A first stress release layer FSL1 may be provided on the top surface of the first stack ST1 and the top surface of the second interlayer insulating layer ILD2. The first stress release layer FSL1 may be interposed between the first stack ST1 and the second stack ST2. The first stress release layer FSL1 may be interposed between the second interlayer insulating layer ILD2 and the third interlayer insulating layer ILD3.

The first stress release layer FSL1 may be the same as the stress release layer FSL previously described with reference to FIG. 2A. The first stress release layer FSL1 may be formed of or include organosilicon polymer. For example, the first stress release layer FSL1 may be formed of or include polydimethylsiloxane.

The first stress release layer FSL1 may contain carbon (C) in a relatively high concentration. Thus, a carbon concentration (e.g., atomic fraction) of the first stress release layer FSL1 may be higher than a carbon concentration of each of the second and third interlayer insulating layers ILD2 and ILD3. The carbon concentration of the first stress release layer FSL1 may be higher than a carbon concentration of the second insulating layer IL2 below the first stress release layer FSL1.

The first stress release layer FSL1 may contain silicon (Si) in a relatively low concentration. Thus, a silicon concentration of the first stress release layer FSL1 may be lower than a silicon concentration of each of the second and third interlayer insulating layers ILD2 and ILD3. The silicon concentration of the first stress release layer FSL1 may be lower than a silicon concentration of the second insulating layer IL2 below the first stress release layer FSL1.

The first stress release layer FSL1 may have a relatively low density. Thus, a density of the first stress release layer FSL1 may be lower than a density of each of the second and third interlayer insulating layers ILD2 and ILD3. The density of the first stress release layer FSL1 may be lower than a density of the second insulating layer IL2 below the first stress release layer FSL1.

A second stress release layer FSL2 may be provided on the top surface of the second stack ST2 and the top surface of the third interlayer insulating layer ILD3. The second stress release layer FSL2 may be interposed between the second stack ST2 and the fourth interlayer insulating layer ILD4. The second stress release layer FSL2 may be interposed between the third interlayer insulating layer ILD3 and the fourth interlayer insulating layer ILD4.

The second stress release layer FSL2 may be configured to have the same features as the stress release layer FSL previously described with reference to FIG. 2A. The second stress release layer FSL2 may be formed of or include organosilicon polymer. For example, the second stress release layer FSL2 may be formed of or include the same material as the first stress release layer FSL1.

As previously described with reference to the first stress release layer FSL1, the second stress release layer FSL2 may have a high carbon concentration, a low silicon concentration, and a low density, compared to each of the fourth insulating layer IL4, the third interlayer insulating layer ILD3, and the fourth interlayer insulating layer ILD4.

A third stress release layer FSL3 may be provided on the top surface of the fourth interlayer insulating layer ILD4. The third stress release layer FSL3 may be configured to have the same features as the stress release layer FSL previously described with reference to FIG. 2A. The third stress release layer FSL3 may be formed of or include organosilicon polymer. In an embodiment, the third stress release layer FSL3 may be formed of or include the same material as the first stress release layer FSL1.

The first to third stress release layers FSL1, FSL2, and FSL3 may be respectively located at levels that are different from each other. In an embodiment, the first to third stress release layers FSL1, FSL2, and FSL3 may have thicknesses different from each other. In another embodiment, the first to third stress release layers FSL1, FSL2, and FSL3 may have the same thickness.

The first stress release layer FSL1 may be used in an etching process, which is performed to form the first vertical extended portion VEP1 and the expanded portion EXP of the vertical channel structure VS. A top surface of the first stress release layer FSL1 may be located at the same level as (i.e., coplanar with) the top surface of the expanded portion EXP.

The second stress release layer FSL2 may be used in an etching process, which is performed to form the second vertical extended portion VEP2 of the vertical channel structure VS. A top surface of the second stress release layer FSL2 may be located at the same level as the top surface of the vertical channel structure VS. More specifically, the top surface of the second stress release layer FSL2 may be located at the same level as the top surface of the conductive pad PAD.

The third stress release layer FSL3 may be used in an etching process, which is performed to form at least one of the separation structure SPS, the cell contact plug CPLG, the source contact plug SPLG, and the penetration via TVS. A top surface of the third stress release layer FSL3 may be located at the same level as the top surface of the at least one of the separation structure SPS, the cell contact plug CPLG, the source contact plug SPLG, and the penetration via TVS.

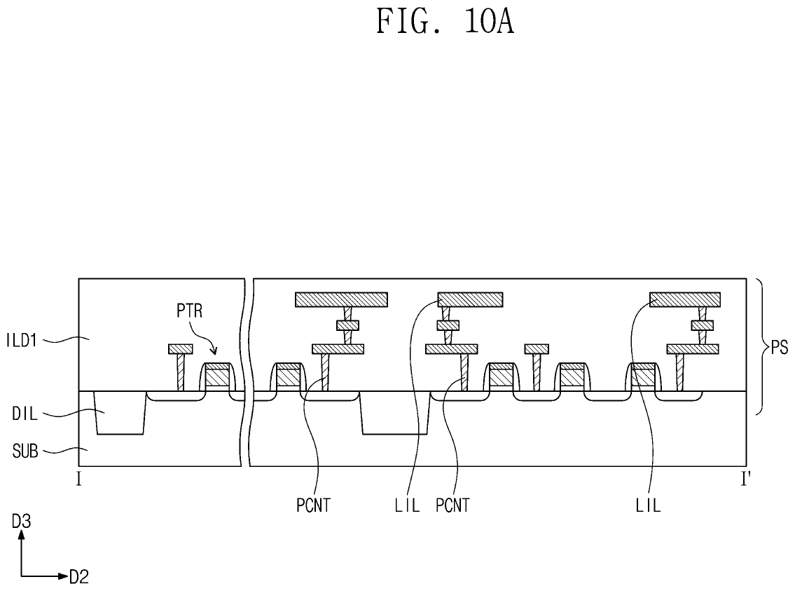

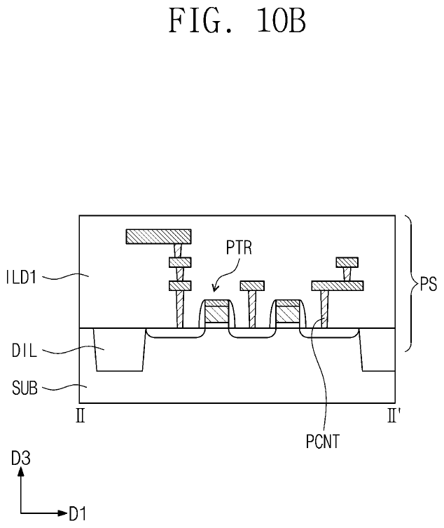

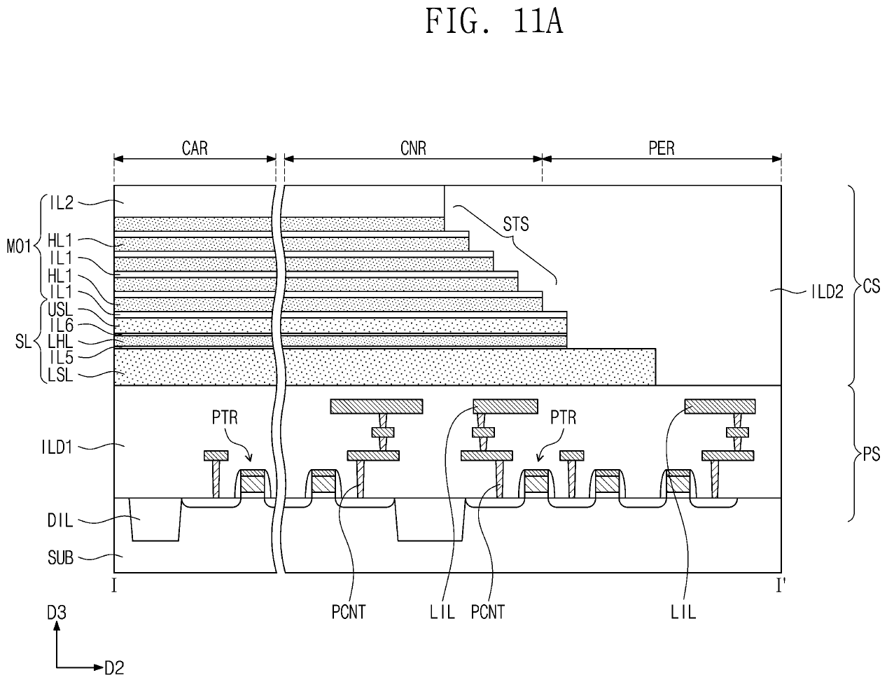

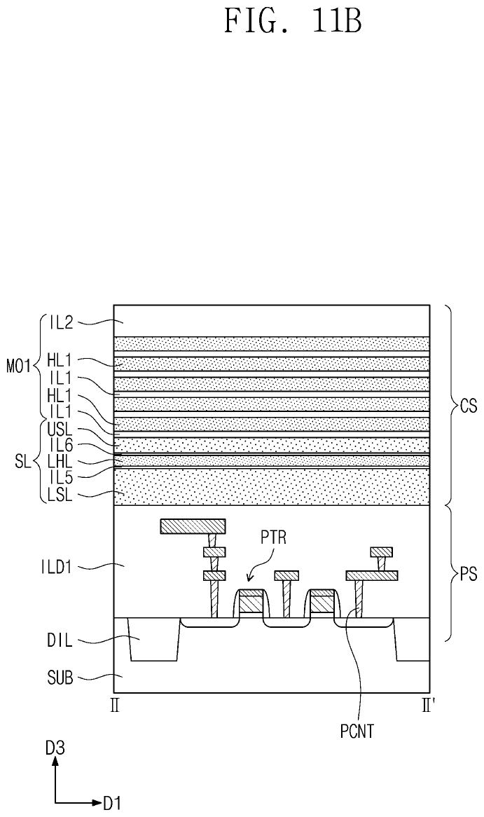

FIGS. 10A, 11A, 12A, 13A, 14A, 15A, 16A, and 17A are sectional views taken along a line I-I′ of FIG. 8 to illustrate a method of fabricating a semiconductor device according to an embodiment of the inventive concept. FIGS. 10B, 111B, 12B, 13B, 14B, 15B, 16B, and 17B are sectional views taken along a line II-II′ of FIG. 8 to illustrate a method of fabricating a semiconductor device according to an embodiment of the inventive concept.

Referring to FIGS. 8, 10A, and 10B, the lower level layer PS may be formed on the first substrate SUB. The formation of the lower level layer PS may include forming the peripheral transistors PTR on the first substrate SUB and forming the lower interconnection lines LIL on the peripheral transistors PTR. For example, the formation of the peripheral transistors PTR may include forming the device isolation layer DIL on the first substrate SUB to define active regions, forming a gate insulating layer and a gate electrode on the active regions, and injecting impurities into the active regions to form a source/drain region. The first interlayer insulating layer ILD1 may be formed to cover the peripheral transistors PTR and the lower interconnection lines LIL.

Referring to FIGS. 8, 11A, and 111B, the upper level layer CS including the cell array region CAR, the cell contact region CNR, and the peripheral region PER may be formed on the first interlayer insulating layer ILD1. In detail, the second substrate SL may be formed on the first interlayer insulating layer ILD1. The formation of the second substrate SL may include sequentially forming the lower semiconductor layer LSL, the fifth insulating layer IL5, the lower sacrificial layer LHL, the sixth insulating layer IL6, and the upper semiconductor layer USL. For example, the lower semiconductor layer LSL and the upper semiconductor layer USL may be formed of or include a semiconductor material (e.g., polysilicon). The fifth and sixth insulating layers IL5 and IL6 may be formed of or include silicon oxide, and the lower sacrificial layer LHL may be formed of or include silicon nitride or silicon oxynitride.

A first mold layer MO1 may be formed on the second substrate SL. In detail, the first insulating layers IL1 and first sacrificial layers HL1 may be alternately stacked on the upper semiconductor layer USL to form the first mold layer MO1. The second insulating layer IL2 may be formed as the uppermost layer of the first mold layer MO1.

The first insulating layers IL1, the first sacrificial layers HL1, and the second insulating layer IL2 may be deposited using a thermal chemical vapor deposition (thermal CVD) process, a plasma-enhanced chemical vapor deposition (Plasma enhanced CVD) process, a physical chemical vapor deposition (physical CVD) process, or an atomic layer deposition (ALD) process. The first insulating layers IL1 and the second insulating layer IL2 may be formed of or include silicon oxide, and the first sacrificial layers HL1 may be formed of or include silicon nitride or silicon oxynitride.

The staircase structure STS may be formed in the first mold layer MO1 of the cell contact region CNR. In detail, a cyclic process may be performed on the first mold layer MO1 to form the staircase structure STS on the cell contact region CNR. The formation of the staircase structure STS may include forming a mask pattern (not shown) on the first mold layer MO1 and performing a cyclic patterning process using the mask pattern several times. Each cyclic patterning process may include a step of etching a portion of the first mold layer MO1 using the mask pattern as an etch mask and a trimming step of reducing the mask pattern.

The second interlayer insulating layer ILD2 may be formed on the first mold layer MO1. The formation of the second interlayer insulating layer ILD2 may include forming an insulating layer to cover the first mold layer MO1 and performing a planarization process on the insulating layer to expose the second insulating layer IL2.

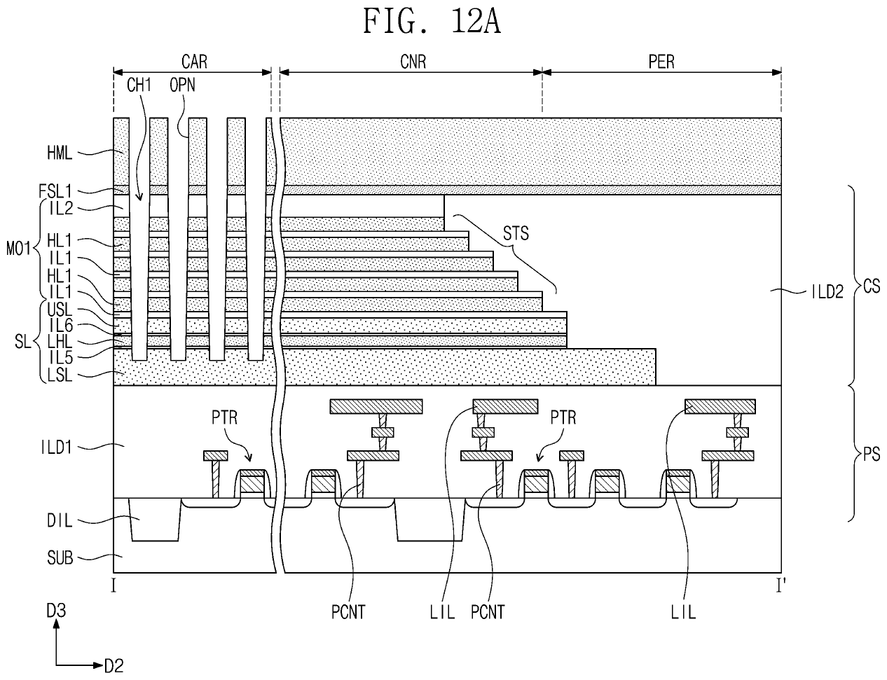

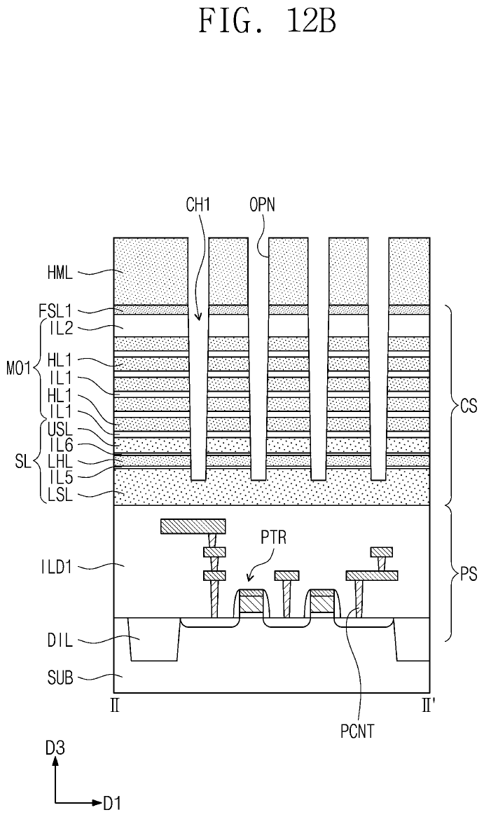

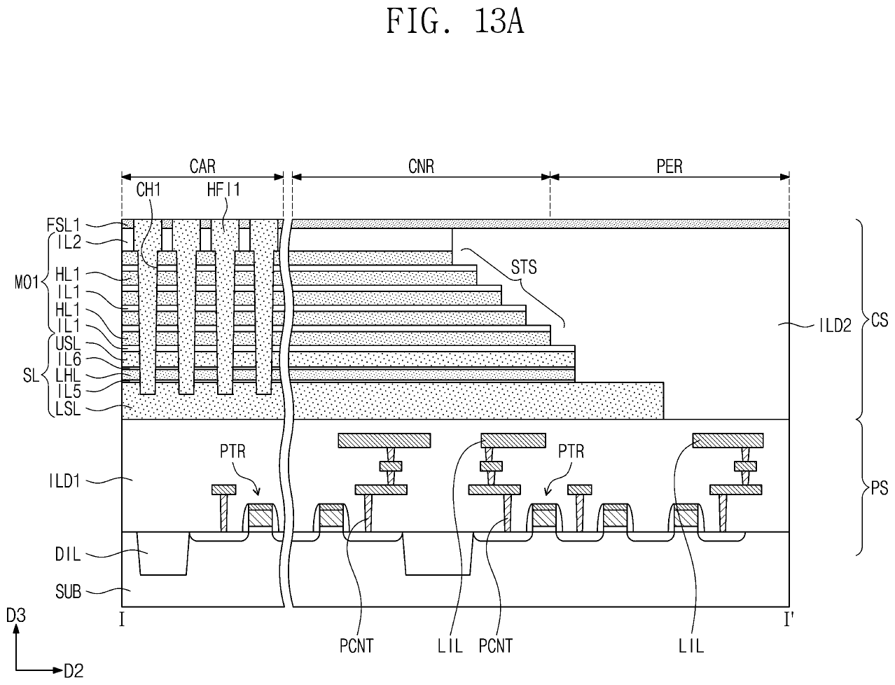

Referring to FIGS. 8, 12A, and 12B, the first stress release layer FSL1 may be formed on the top surface of the first mold layer MO1 and the top surface of the second interlayer insulating layer ILD2. The first stress release layer FSL1 may be configured to have the same features as the stress release layer FSL previously described with reference to FIG. 2A. The first stress release layer FSL1 may be formed of or include organosilicon polymer. The first stress release layer FSL1 may be formed by a flowable chemical vapor deposition process, a spin coating process, or a spray coating process.

The hard mask layer MIL may be formed on the first stress release layer FSL1. The hard mask layer MIL may be configured to have the same features as the hard mask layer MIL previously described with reference to FIG. 2B. For example, the hard mask layer HML may include an amorphous carbon layer.

As previously described with reference to FIG. 3, the first stress release layer FSL1 may be used to release or reduce a stress caused by the hard mask layer HML. The first stress release layer FSL1 may serve as a stress damper against the hard mask layer HML. Due to the presence of the first stress release layer FSL1, it may be possible to reduce or prevent the first substrate SUB and the first mold layer MO1 from being bent.

The hard mask layer MIL may be patterned through a photolithography process. A plurality of openings OPN may be formed in the hard mask layer MIL. In the present embodiment, since the first stress release layer FSL1 reduces or prevents the first mold layer MO1 and the hard mask layer HML from being bent, the photolithography process may be performed with improved accuracy. In other words, it may be possible to form the openings OPN in the hard mask layer HML stably (e.g., without any process failure).

In an embodiment, the photolithography process may be a lithography process performed using an extreme ultraviolet (EUV) light. In an embodiment, the EUV light may have a wavelength ranging from 4 nm and 124 nm and, in particular, from 4 nm and 20 nm and may be, for example, an ultraviolet light having a wavelength of 13.5 nm. The EUV light may have an energy of 6.21 eV to 124 eV (in particular, 90 eV to 95 eV).

The EUV lithography process may include a step of exposing a photoresist layer to extreme ultraviolet (EUV) light and a step of developing the exposed photoresist layer. As an example, the photoresist layer may be an organic photoresist layer containing an organic polymer (e.g., polyhydroxystyrene). The organic photoresist layer may further include a photosensitive compound which can be reacted with the EUV light. The organic photoresist layer may further contain a material having high EUV absorptivity (e.g., organometallic materials, iodine-containing materials, or fluorine-containing materials). As another example, the photoresist layer may be an inorganic photoresist layer containing an inorganic material (e.g., tin oxide).

The photoresist layer may be formed to have a relatively small thickness. Photoresist patterns may be formed by developing the photoresist layer, which is exposed to the EUV light. When viewed in a plan view, the photoresist patterns may be formed to have a line shape extending in a specific direction, an island shape, a zigzag shape, a honeycomb shape, or a circular shape, but the inventive concept is not limited to these examples. In the present embodiment, the openings OPN may be formed by patterning the hard mask layer HML using the photoresist patterns as an etch mask.

In a comparative example of the inventive concept, a multi-patterning technology (MPT) using two or more photomasks is required to form fine-pitch patterns on the wafer. By contrast, in the EUV lithography process according to an embodiment of the inventive concept, it may be possible to form the openings OPN at a fine pitch, even when just one photo mask is used.

For example, the minimum pitch between the openings OPN, which are realized by the EUV lithography process according to the present embodiment, may be less than or equal to 45 nm. That is, by using the EUV lithography process according to an embodiment of the inventive concept, it may be possible to precisely and finely form the openings OPN, without a multi-patterning technology.

First channel holes CH1 may be formed by anisotropically etching the first mold layer MO1 using the hard mask layer HML as an etch mask. The first channel holes CH1 may be formed to penetrate the first mold layer MO1 on the cell array region CAR. Each of the first channel holes CH1 may be formed to expose the lower semiconductor layer LSL.

The anisotropic etching process, which is performed to form the first channel holes CH1, may include a plasma etching process, a reactive ion etching (RIE) process, an inductively-coupled-plasma reactive-ion-etching (ICP-RIE) process, or an ion beam etching (IBE) process. The anisotropic etching process according to the present embodiment may be performed using a high-power plasma.

In the present embodiment, a bottom surface of the first substrate SUB may not be covered with or may be free of the stress layer STL shown in FIG. 1C. In the present embodiment, the bottom surface of the first substrate SUB may be exposed to the outside, as shown in FIG. 2C. Thus, during the anisotropic etching process of the first mold layer MO1, it may be possible to uniformly apply a ground voltage to the first substrate SUB and thereby to reduce or prevent a process failure, such as arcing.

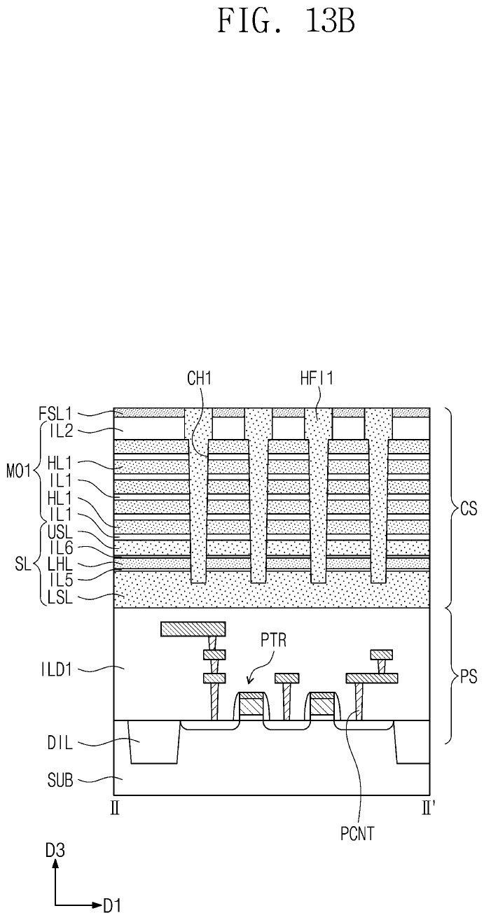

Referring to FIGS. 8, 13A, and 13B, the hard mask layer MIL may be selectively removed. In an embodiment, the first stress release layer FSL1 may not be removed. In another embodiment, the first stress release layer FSL1 may be selectively or partially removed.

An upper portion of each of the first channel holes CH1 may be expanded. Accordingly, a diameter of the first channel hole CH1 in the second insulating layer IL2 may be abruptly increased. First sacrificial pillars HFI1 may be formed to fill the first channel holes CH1, respectively.

In detail, the formation of the first sacrificial pillars HFI1 may include forming a first sacrificial mask layer to fill the first channel holes CH1 and planarizing the first sacrificial mask layer to expose a top surface of the first stress release layer FSL1. A top surface of the first sacrificial pillar HFI1 may be coplanar with the top surface of the first stress release layer FSL1. The first sacrificial mask layer may be formed of or include polysilicon.

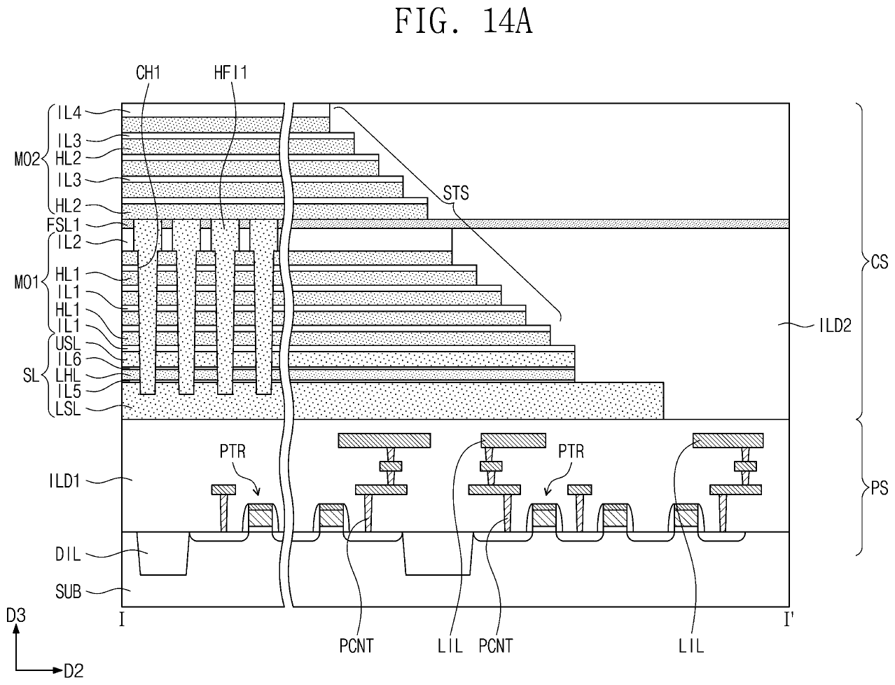

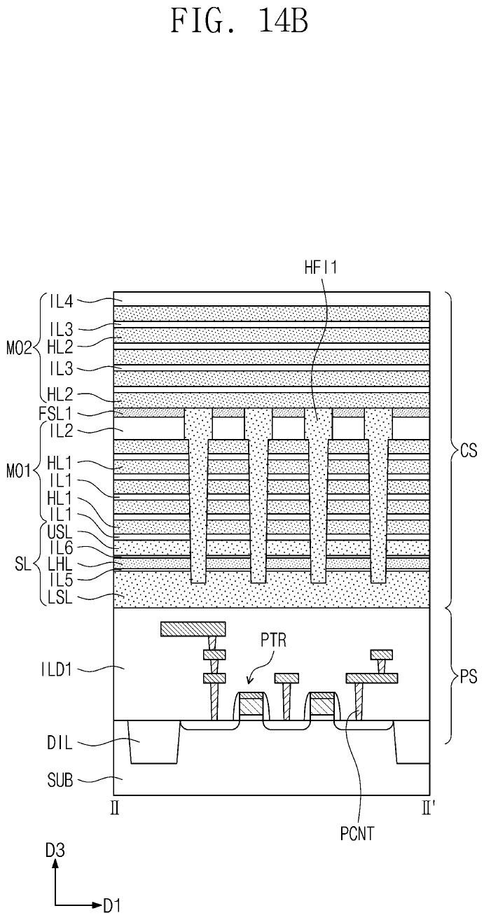

Referring to FIGS. 8, 14A, and 14B, a second mold layer MO2 may be formed on the first mold layer MO1 of the cell array region CAR. The formation of the second mold layer MO2 may include alternately stacking the third insulating layers IL3 and second sacrificial layers HL2 on the first mold layer MO1 and performing a cyclic process on a stack, in which the third insulating layers IL3 and the second sacrificial layers HL2 are stacked, to form the staircase structure STS. The cyclic process may be performed in the same manner as the previously-described process for forming the staircase structure STS of the first mold layer MOL.

The second mold layer MO2 may have the staircase structure STS. The staircase structure STS of the second mold layer MO2 may be continued from the staircase structure STS of the first mold layer MO1.

The fourth insulating layer IL4 may be formed at the uppermost level of the second mold layer MO2. The third insulating layers IL3 and the fourth insulating layer IL4 may include a silicon oxide layer, and the second sacrificial layers HL2 may include a silicon nitride layer or a silicon oxynitride layer. The second sacrificial layers HL2 may be formed of or include the same material as the first sacrificial layers HL1.

The third interlayer insulating layer ILD3 may be formed on the second mold layer MO2. The formation of the third interlayer insulating layer ILD3 may include forming an insulating layer to cover the second mold layer MO2 and performing a planarization process on the insulating layer to expose the fourth insulating layer IL4. The third interlayer insulating layer ILD3 may cover the staircase structure STS of the second mold layer MO2.

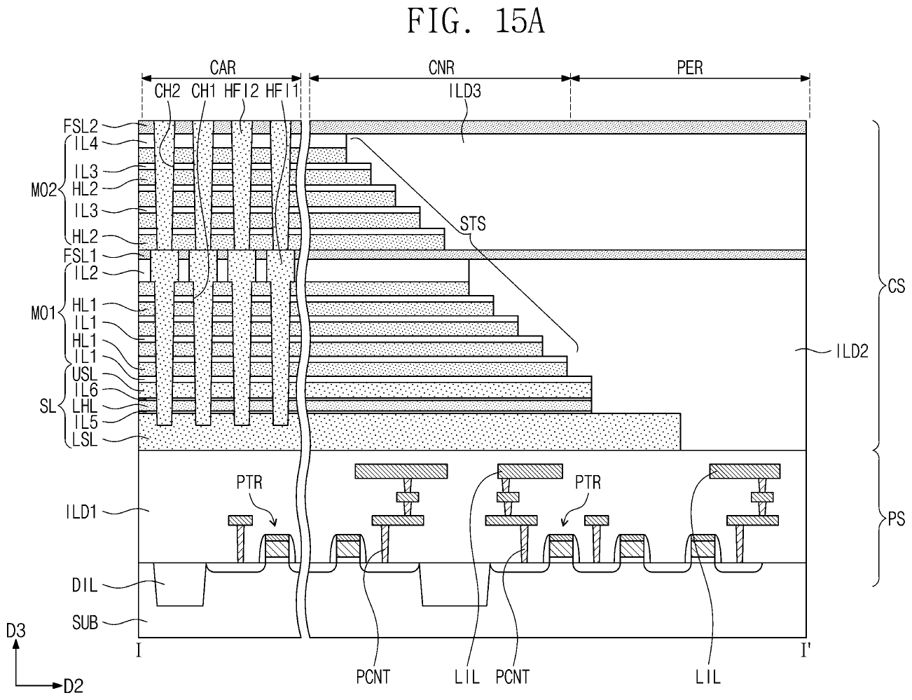

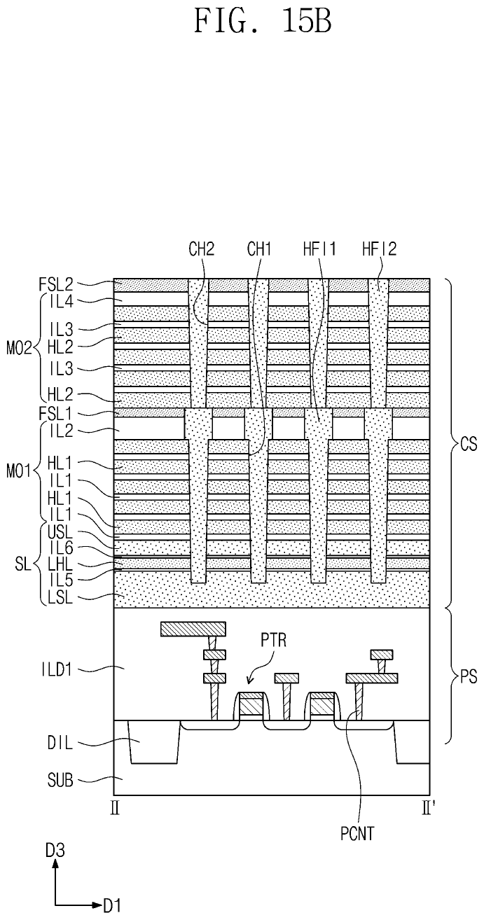

Referring to FIGS. 8, 15A, and 15B, the second stress release layer FSL2 may be formed on a top surface of the second mold layer MO2 and the top surface of the third interlayer insulating layer ILD3. The second stress release layer FSL2 may be configured to have the same features as the first stress release layer FSL1 described above.

The second stress release layer FSL2 may be used to form second channel holes CH2 penetrating the second mold layer MO2 of the cell array region CAR. The second channel holes CH2 may be formed to be vertically overlapped with the first sacrificial pillars HFI1, respectively. The second channel holes CH2 may be formed by substantially the same method as that for the first channel holes CH1 previously described with reference to FIGS. 12A and 12B.

Second sacrificial pillars HFI2 may be formed to fill the second channel holes CH2, respectively. The second sacrificial pillars HFI2 may be vertically overlapped with the first sacrificial pillars HFI1, respectively. In detail, the formation of the second sacrificial pillars HFI2 may include forming a second sacrificial mask layer to fill the second channel holes CH2 and planarizing the second sacrificial mask layer to expose the top surface of the fourth interlayer insulating layer ILD4. For example, the second sacrificial mask layer may be formed of or include polysilicon. The second sacrificial pillars HFI2 may be formed of or include the same material as the first sacrificial pillars HFI1.

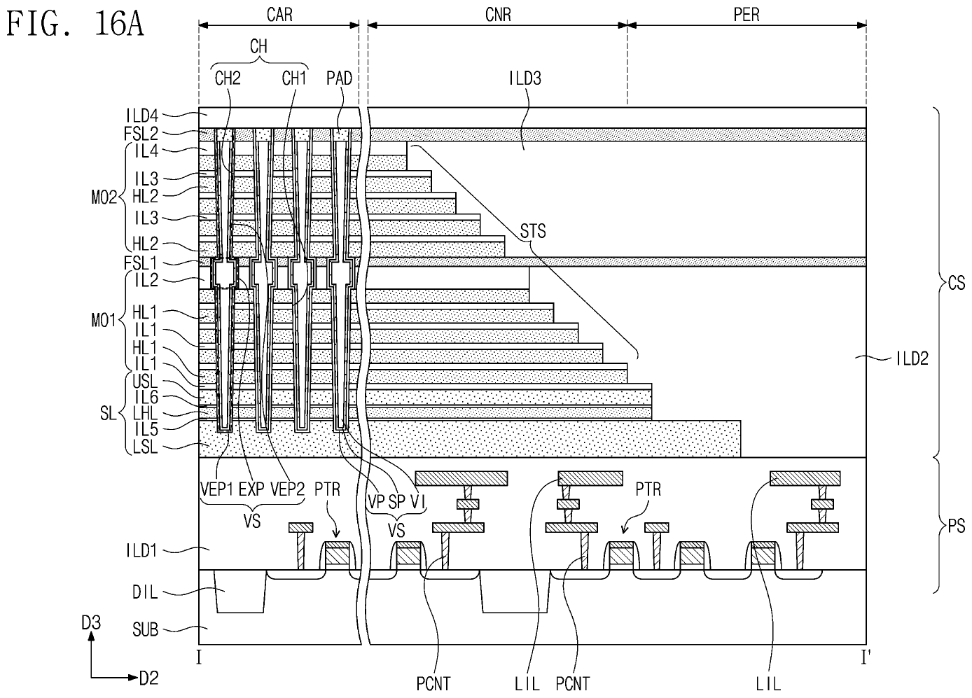

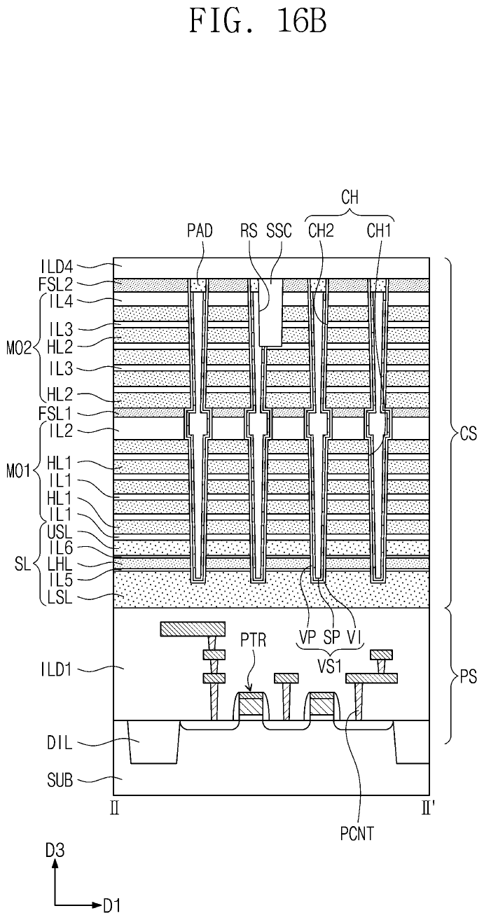

Referring to FIGS. 8, 16A, and 16B, the first and second sacrificial pillars HFI1 and HFI2 may be selectively removed from the first and second channel holes CH1 and CH2. The first and second channel holes CH1 and CH2, from which the first and second sacrificial pillars HFI1 and HFI2 are removed, may be connected to each other to form a single channel hole CH.

The vertical channel structures VS may be formed in the channel holes CH, respectively. The formation of the vertical channel structure VS may include sequentially forming the vertical insulating pattern VP, the vertical semiconductor pattern SP, and the insulating gapfill pattern VI on an inner surface of the channel hole CH. The vertical insulating pattern VP and the vertical semiconductor pattern SP may be conformally formed. The conductive pad PAD may be formed in an upper portion of each of the vertical channel structures VS.

A recess RS defining the cutting structure SSC may be formed in an upper portion of the second mold layer MO2. The recess RS may be formed to penetrate two uppermost ones of the second sacrificial layers HL2 of the second mold layer MO2. The recess RS may also be formed to partially penetrate an upper portion of the vertical channel structure VS overlapped with the same. The cutting structure SSC may be formed by filling the recess RS with an insulating material. The fourth interlayer insulating layer ILD4 may be formed on the cutting structure SSC and the second stress release layer FSL2.

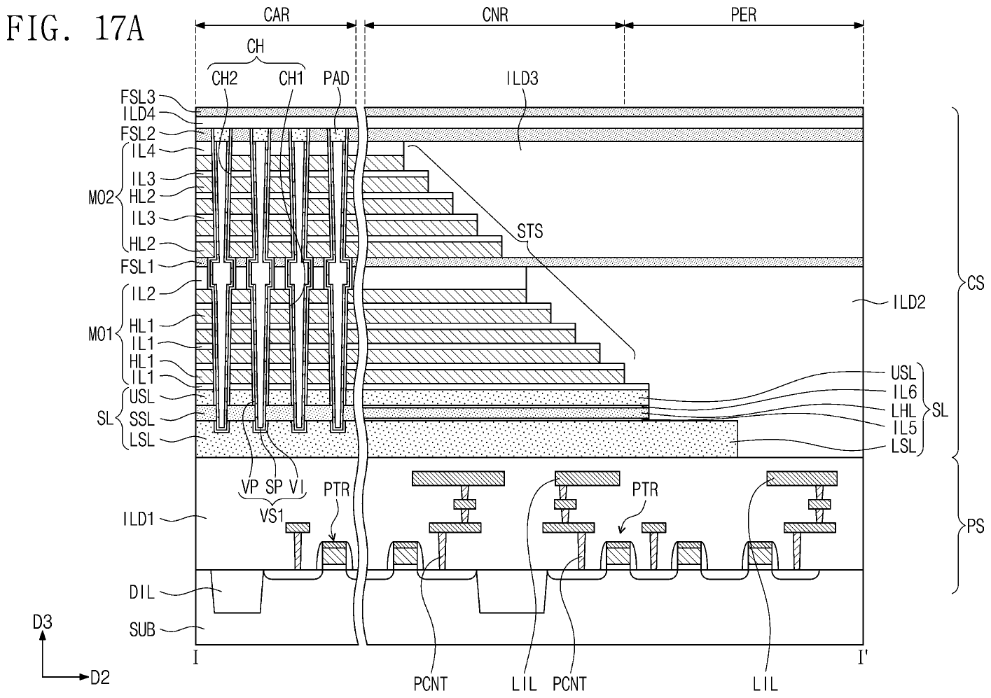

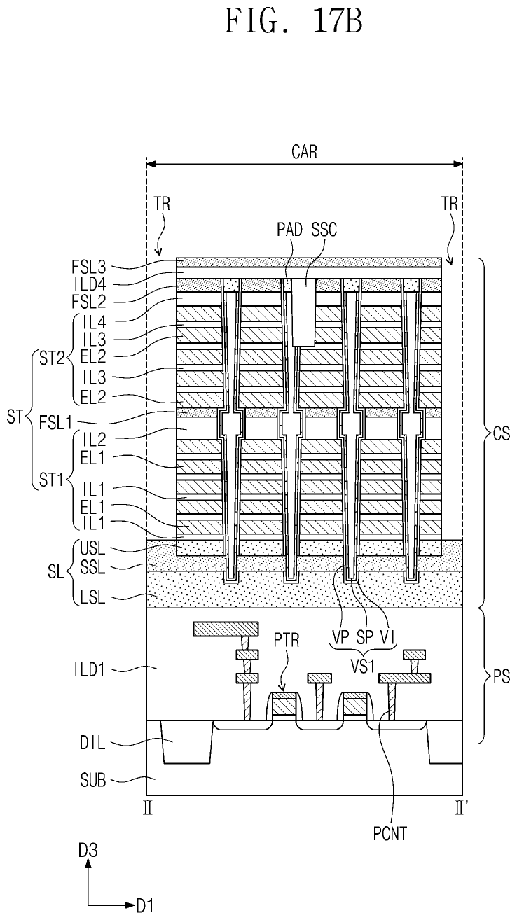

Referring to FIGS. 8, 17A, and 17B, the third stress release layer FSL3 may be formed on the top surface of the fourth interlayer insulating layer ILD4. The third stress release layer FSL3 may be configured to have the same features as the first stress release layer FSL1 described above.

The third stress release layer FSL3 may be used to form trenches TR penetrating the first and second mold layers MO1 and MO2. The trenches TR may be formed by a method that is similar to that the method of forming the first channel holes CH1 previously described with reference to FIGS. 12A and 12B. The trenches TR may be formed to define the separation structures SPS.

The trench TR may be formed to expose the lower semiconductor layer LSL. The trench TR may be formed to expose side surfaces of the first and second sacrificial layers HL1 and HL2. The trench TR may expose the side surface of the fifth insulating layer IL5, the side surface of the lower sacrificial layer LHL, and the side surface of the sixth insulating layer IL6.

In the cell array region CAR, the lower sacrificial layer LHL exposed by the trenches TR may be replaced with the source semiconductor layer SSL. In detail, the lower sacrificial layer LHL exposed by the trenches TR may be selectively removed. As a result of the removal of the lower sacrificial layer LHL, a lower portion of the vertical insulating pattern VP of each of the vertical channel structures VS may be exposed.

The exposed lower portion of the vertical insulating pattern VP may be selectively removed. Accordingly, a lower portion of the vertical semiconductor pattern SP may be exposed. The fifth insulating layer IL5 and the sixth insulating layer IL6 may be removed during removing the lower portion of the vertical insulating pattern VP.

The source semiconductor layer SSL may be formed in a space, from which the fifth insulating layer IL5, the lower sacrificial layer LHL, and the sixth insulating layer IL6 are removed. The source semiconductor layer SSL may be in direct contact with the exposed lower portion of the vertical semiconductor pattern SP. The source semiconductor layer SSL may be in direct contact with the lower semiconductor layer LSL therebelow. The source semiconductor layer SSL may be in direct contact with the upper semiconductor layer USL thereon. The lower semiconductor layer LSL, the source semiconductor layer SSL, and the upper semiconductor layer USL in the cell array region CAR may constitute the second substrate SL.

In the cell array region CAR, the first and second sacrificial layers HL1 and HL2 exposed by the trenches TR may be replaced with the first and second electrodes EL1 and EL2 to form the cell array structure ST. In detail, the first and second sacrificial layers HL1 and HL2 exposed through the trenches TR may be selectively removed. The first and second electrodes EL1 and EL2 may be formed in empty spaces, respectively, which are formed by the removing of the first and second sacrificial layers HL1 and HL2.

Referring back to FIGS. 8, 9A, and 9B, the separation structures SPS may be formed to fill the trenches TR, respectively. The cell contact plugs CPLG may be formed to be connected to the staircase structure STS of the cell array structure ST. The source contact plug SPLG may be formed to be connected to the lower semiconductor layer LSL. The penetration via TVS may be formed to be connected to the lower interconnection line LIL of the lower level layer PS. In an embodiment, an anisotropic etching process, which is performed to form the cell contact plugs CPLG, the source contact plug SPLG, and the penetration via TVS, may be performed using a remaining portion of the third stress release layer FSL3.

The bit line contacts BPLG may be formed to penetrate the third stress release layer FSL3 and the fourth interlayer insulating layer ILD4 and to be coupled to the conductive pads PAD, respectively. At least one of the bit line contacts BPLG may be formed to be coupled to the conductive pad PAD that is in contact with the cutting structure SSC.

The bit lines BL, which are respectively connected to the bit line contacts BPLG, may be formed on the third stress release layer FSL3. The first upper interconnection lines UIL1, which are respectively connected to the cell contact plugs CPLG, may be formed on the third stress release layer FSL3. The second upper interconnection line UIL2 and the third upper interconnection line UIL3, which are respectively connected to the source contact plug SPLG and the penetration via TVS, may be formed on the third stress release layer FSL3.

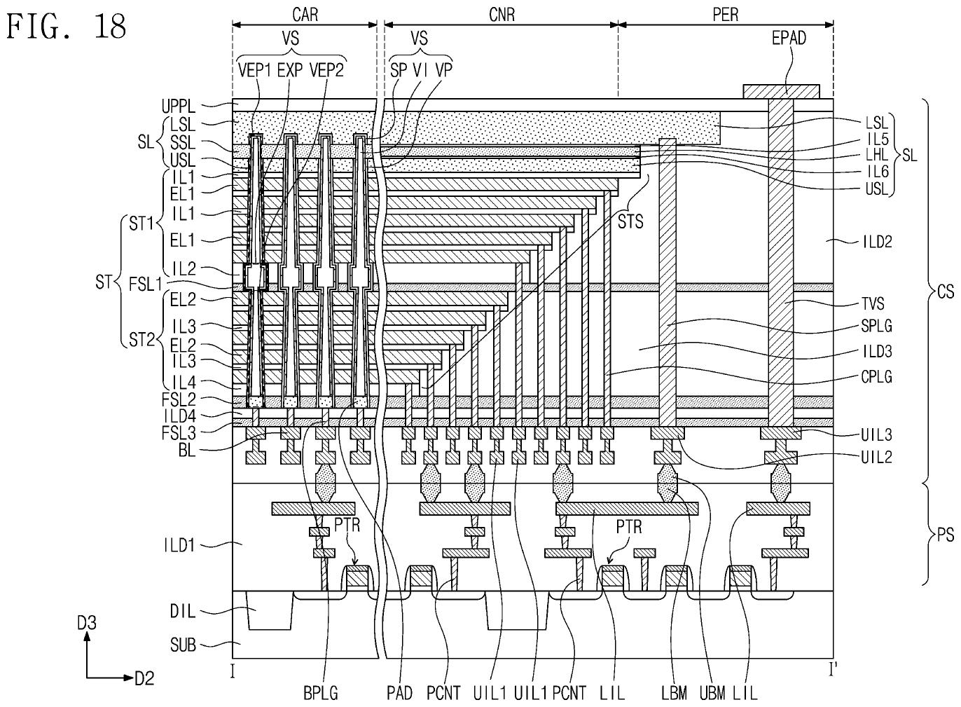

FIG. 18 is a sectional view taken along the line I-I′ of FIG. 8 to illustrate a semiconductor device according to an embodiment of the inventive concept. In the following description of the present embodiment, an element previously described with reference to FIGS. 8, 9A, and 9B may be identified by a similar or identical reference number without repeating an overlapping description thereof.

Referring to FIG. 18, the semiconductor device according to the present embodiment may have a chip-to-chip (C2C) structure. The C2C structure may be formed by fabricating an upper chip, which includes the upper level layer CS, on a first wafer, fabricating a lower chip, which includes the lower level layer PS, on a second wafer different from the first wafer, and bonding the upper chip to the lower chip at or along an interface therebetween. The upper and lower chips may be bonded to each other by a wafer bonding method and may be substantially the same as, for example, the semiconductor chip 2200a previously described with reference to FIG. 7.

The wafer bonding method may be a method of electrically connecting a bonding metal, which is formed in the uppermost metal layer of the upper chip, to a bonding metal, which is formed in the uppermost metal layer of the lower chip. In the case where the bonding metal is formed of copper (Cu), the bonding method may be a Cu—Cu bonding method, but in an embodiment, the bonding metal may be formed of or include aluminum or tungsten.

The upper level layer CS of the upper chip may be configured to have substantially the same features as the upper level layer CS including the cell array structure ST, previously described with reference to FIGS. 8, 9A, and 9B. The lower level layer PS of the lower chip may be configured to have substantially the same features as the lower level layer PS including the peripheral transistors PTR previously described with reference to FIGS. 8, 9A, and 9B.

Lower bonding metals LBM may be provided at the uppermost level of the lower level layer PS. Each of the lower bonding metals LBM may be connected to a corresponding one of the lower interconnection line LIL. Upper bonding metals UBM may be provided at the lowermost level of the upper level layer CS. Each of the upper bonding metals UBM may be connected to a corresponding one of upper interconnection lines UIL1-UIL3.

Each of the lower bonding metals LBM may be connected to a corresponding one of the upper bonding metal UBM by a bonding method. Since the lower bonding metal LBM is connected to the upper bonding metal UBM, the lower chip including the lower level layer PS may be connected to the upper chip including the upper level layer CS. The lower bonding metals LBM and the upper bonding metals UBM may be formed of or include at least one of aluminum, copper, or tungsten.

An upper insulating layer UPPL may be provided on the second substrate SL. An input/output pad EPAD may be provided on the upper insulating layer UPPL. The input/output pad EPAD may be electrically connected to the peripheral transistor PTR in the lower level layer PS through the penetration via TVS.

In the semiconductor device according to the present embodiment, the upper level layer CS of the upper chip may include the first to third stress release layers FSL1-FSL3 previously described with reference to FIGS. 8, 9A, and 9B. The first to third stress release layers FSL1-FSL3 may be respectively provided at different levels from each other.

According to an embodiment of the inventive concept, a stress release layer may be provided between a mold layer and a hard mask layer to reduce a stress exerted from the hard mask layer. The stress release layer may reduce or prevent a substrate from having a warpage issue and may allow the substrate to have a flat shape even when the hard mask layer is removed. As a result, it may be possible to improve accuracy in a photolithography process on the hard mask layer and to reduce or prevent an arcing failure from occurring in a process of etching the mold layer.

While example embodiments of the inventive concept have been particularly shown and described, it will be understood by one of ordinary skill in the art that variations in form and detail may be made therein without departing from the scope of the attached claims.

1. A semiconductor device, comprising:
a substrate;
a cell array structure on the substrate, the cell array structure comprising a plurality of electrodes that are stacked and spaced apart from each other;
a vertical channel structure that penetrates the cell array structure and is electrically connected to the substrate;
a conductive pad in an upper portion of the vertical channel structure;
an interlayer insulating layer on the cell array structure;
a bit line on the cell array structure and electrically connected to the conductive pad; and
a first stress release layer between the cell array structure and the bit line on a top surface of the interlayer insulating layer,
wherein the first stress release layer comprises organosilicon polymer, and
a carbon concentration of the first stress release layer is higher than a carbon concentration of the interlayer insulating layer.

2. The semiconductor device of claim 1, further comprising a bit line contact electrically connecting the bit line to the conductive pad, wherein a top surface of the first stress release layer is at a same level as a top surface of the conductive pad.

3. The semiconductor device of claim 1, wherein the first stress release layer comprises carbon (C), hydrogen (H), silicon (Si), and oxygen (O),
the carbon concentration of the first stress release layer is about 20 at % to 40 at %,
a silicon concentration of the first stress release layer is about 3 at % to 16 at %, and
an oxygen concentration of the first stress release layer is about 3 at % to 16 at %.

4. The semiconductor device of claim 1, wherein the organosilicon polymer comprises a unit of following chemical formula 1, a unit of following chemical formula 2, or a combination of the units of the following chemical formulas 1 and 2: 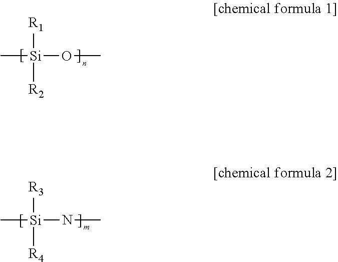
where R1, R2, R3, and R4 are each independently a hydrogen, an alkyl group having 1 to 5 carbon atoms, an alkenyl group having 2 to 6 carbon atoms, an alkynyl group having 2 to 6 carbon atoms, an alkoxy group having 1 to 5 carbon atoms, an aryl group having 6 to 10 carbon atoms, a thiol group, a thiolalkyl group having 1 to 5 carbon atoms, a fluoroalkyl group having 1 to 5 carbon atoms, or an aminoalkyl group having 1 to 5 carbon atoms, and
each of n and m is an integer between 100 and 10,000.

5. The semiconductor device of claim 1, wherein a density of the first stress release layer is lower than a density of the interlayer insulating layer.

6. The semiconductor device of claim 1, wherein a silicon concentration of the first stress release layer is lower than a silicon concentration of the interlayer insulating layer.

7. The semiconductor device of claim 1, wherein the cell array structure comprises a first stack and a second stack on the first stack,
the semiconductor device further comprises a second stress release layer between the first stack and the second stack, and
the second stress release layer comprises a same organosilicon polymer as the first stress release layer.

8. The semiconductor device of claim 1, further comprising:
a separation structure that penetrates the cell array structure and horizontally separates the plurality of electrodes from each other;
a source contact plug vertically extending from a first upper interconnection line to the substrate; and
a penetration via vertically extending from a second upper interconnection line to a region below the substrate,
wherein a top surface of the first stress release layer is at a same level as a top surface of at least one of the separation structure, the source contact plug, or the penetration via.

9. The semiconductor device of claim 1, further comprising:
a lower level layer, which is below the substrate and comprises a peripheral circuit.

10. The semiconductor device of claim 1, wherein a surface of the substrate opposite the first stress release layer is free of stress release layers thereon.

11. A semiconductor device, comprising:
a substrate;
a first stack comprising a plurality of first electrodes stacked on the substrate and spaced apart from each other;
a second stack comprising a plurality of second electrodes stacked on the first stack and spaced apart from each other;
a first stress release layer between the first stack and the second stack; and
a vertical channel structure that penetrates the first stack, the second stack, and the first stress release layer and is electrically connected to the substrate,
wherein the first stress release layer comprises organosilicon polymer,
the first stress release layer comprises carbon (C), hydrogen (H), silicon (Si), and oxygen (O),
a carbon concentration of the first stress release layer is about 20 at % to 40 at %,
a silicon concentration of the first stress release layer is about 3 at % to 16 at %, and
an oxygen concentration of the first stress release layer is about 3 at % to 16 at %.

12. The semiconductor device of claim 11, further comprising:
a second stress release layer on the second stack opposite the first stress release layer,
wherein the second stress release layer comprises a same organosilicon polymer as the first stress release layer.

13. The semiconductor device of claim 12, further comprising:
a conductive pad in an upper portion of the vertical channel structure;
a bit line on the cell array structure; and
a bit line contact electrically connecting the bit line to the conductive pad,
wherein a top surface of the second stress release layer is at a same level as a top surface of the conductive pad.

14. The semiconductor device of claim 11, wherein the vertical channel structure comprises:
a first vertical extended portion penetrating the first stack;
a second vertical extended portion penetrating the second stack; and
an expanded portion between the first and second vertical extended portions,
wherein a top surface of the first stress release layer is at a same level as a top surface of the expanded portion.

15. The semiconductor device of claim 11, further comprising:
an interlayer insulating layer on a staircase structure of the first stack,
wherein the first stress release layer is on a top surface of the interlayer insulating layer, and
a density of the first stress release layer is lower than a density of the interlayer insulating layer.

16. An electronic system, comprising:
a semiconductor device, which comprises an input/output pad electrically connected to peripheral circuits; and
a controller, which is electrically connected to the semiconductor device through the input/output pad and is configured to control the semiconductor device,
wherein the semiconductor device comprises:
a lower level layer comprising a first substrate and the peripheral circuits on the first substrate; and
an upper level layer on the lower level layer,
wherein the upper level layer comprises:
a second substrate on the lower level layer;
a cell array structure on the second substrate, the cell array structure comprising a plurality of electrodes stacked and spaced apart from each other;
a vertical channel structure that penetrates the cell array structure and is electrically connected to the second substrate;
an interlayer insulating layer on the cell array structure; and
a stress release layer on the cell array structure and on a top surface of the interlayer insulating layer,
wherein the stress release layer comprises organosilicon polymer, and
a density of the stress release layer is lower than a density of the interlayer insulating layer.

17. The electronic system of claim 16, further comprising:
a conductive pad in an upper portion of the vertical channel structure;
a bit line on the cell array structure; and
a bit line contact electrically connecting the bit line to the conductive pad,
wherein a top surface of the stress release layer is at a same level as a top surface of the conductive pad.

18. The electronic system of claim 16, further comprising:
a separation structure that penetrates the cell array structure and horizontally separates the plurality of electrodes from each other;
a source contact plug vertically extending from a first upper interconnection line to the second substrate; and
a penetration via vertically extending from a second upper interconnection line to the lower level layer,
wherein a top surface of the stress release layer is at a same level as a top surface of at least one of the separation structure, the source contact plug, or the penetration via.

19. The electronic system of claim 16, wherein a carbon concentration of the stress release layer is higher than a carbon concentration of the interlayer insulating layer.

20. The electronic system of claim 16, wherein a silicon concentration of the stress release layer is lower than a silicon concentration of the interlayer insulating layer.

21.-25. (canceled)
